(19) United States
(12) Patent Application Publication
(10) Pub. No.: US 2022/0359268 A1
(43) Pub. Date: Nov. 10, 2022

(54) THROUGH WAFER ISOLATION ELEMENT BACKSIDE PROCESSING

(71) Applicant: TEXAS INSTRUMENTS INCORPORATED, Dallas, TX (US)

(72) Inventors: Scott Robert SUMMERFELT, Garland, TX (US); Benjamin Stassen COOK, Los Gatos, CA (US); Simon Joshua JACOBS, Lucas, TX (US); Baher S. HAROUN, Allen, TX (US)

(21) Appl. No.: 17/683,201

(22) Filed: Feb. 28, 2022

Related U.S. Application Data
(60) Provisional application No. 63/184,019, filed on May 4, 2021.

(51) Int. Cl. H01L 21/762

(52) U.S. Cl. CPC H01L 21/76224; H01L 2224/48225; H01L 2224/16225; H01L 24/48

(57) ABSTRACT

Disclosed herein is an integrated circuit (IC) comprising a semiconductor wafer, a dielectric layer, and an isolation element. The semiconductor wafer has a first wafer portion and a second wafer portion each extending from a frontside surface to a backside surface. The dielectric layer interfaces with the first wafer portion and with the second wafer portion each on the frontside surface. The isolation element has an isolation dielectric material, and the isolation element extends between a first side surface of the first wafer portion and a second side surface of the second wafer portion and from an extension plane of the frontside surface to an extension plane of the backside surface. Also disclosed herein is a system comprising the IC and a package substrate coupled to the IC.

### CROSS-REFERENCE TO RELATED APPLICATIONS

This application claims priority to U.S. Provisional Patent Application No. 63/184,019, which was filed May 4, 2021, which is hereby incorporated herein by reference in its entirety.

### BACKGROUND

An integrated circuit (IC) usually includes multiple devices formed on or in a semiconductor wafer, each having various electrically conductive components tailored for specific applications. Isolation elements are formed between these devices, to prevent unintended electrical communications.

### SUMMARY

In at least one example, an integrated circuit (IC) comprises a semiconductor wafer, a dielectric layer, and an isolation element. The semiconductor wafer has a first wafer portion and a second wafer portion each extending from a frontside surface to a backside surface. The dielectric layer interfaces with the first wafer portion and with the second wafer portion each on the frontside surface. The isolation element has an isolation dielectric material, and the isolation element extends between a first side surface of the first wafer portion and a second side surface of the second wafer portion and from an extension plane of the frontside surface to an extension plane of the backside surface.

In at least one example, an integrated circuit (IC) comprises a semiconductor wafer, a dielectric layer, and an isolation element. The semiconductor wafer has a first wafer portion and a second wafer portion positioned juxtaposed with each other. The first wafer portion has a first front surface and a first back surface, the second wafer portion has a second front surface and a second back surface, the first front surface coplanar with the second front surface, and the first back surface coplanar with the second back surface. The dielectric layer interfaces with the first wafer portion on the first front surface and with the second wafer portion on the second front surface. The isolation element has an isolation dielectric material and extends between the first wafer portion and the second wafer portion, and the isolation element interfaces with at least a portion of the first back surface and a portion of the second back surface.

In at least one example, a system comprises an IC and a package substrate coupled to the IC. The IC comprises a semiconductor wafer, a dielectric layer, and an isolation element. The semiconductor wafer has a first wafer portion and a second wafer portion each extending from a frontside surface to a backside surface. The dielectric layer interfaces with the first wafer portion and with the second wafer portion each on the frontside surface. The isolation element has an isolation dielectric material and extends between a first side surface of the first wafer portion and a second side surface of the second wafer portion and from an extension plane of the frontside surface to an extension plane of the backside surface.

### BRIEF DESCRIPTION OF THE DRAWINGS

For a detailed description of various examples, reference will now be made to the accompanying drawings in which:

FIG. 1 is a cross-sectional view of a system including an IC in various examples;

FIGS. 2A-2H are process flow diagrams of fabricating an IC in various examples;

FIGS. 3A-3L are process flow diagrams of fabricating an IC in various examples;

FIGS. 4A-4E are process flow diagrams of fabricating an IC in various examples;

FIGS. 5A-5P are process flow diagrams of fabricating an IC in various examples;

FIGS. 6A-6Q are process flow diagrams of fabricating an IC in various examples;

FIGS. 7A-7C are profile cross-sectional views of systems including an IC in various examples;

FIGS. 8A-8B are profile cross-sectional views of systems including an IC in various examples;

FIG. 9 is a profile cross-sectional view of a system including an IC in various examples;

FIG. 10 is a flow diagram of a method for fabricating an IC in various examples;

FIG. 11 is a flow diagram of a method for fabricating an IC in various examples;

FIG. 12 is a flow diagram of a method for fabricating an IC in various examples; and

FIG. 13 is a flow diagram of a method for fabricating an IC in various examples.

### DETAILED DESCRIPTION

In some approaches, isolation elements are formed within a semiconductor wafer by etching trenches in the wafer and subsequently filling the trenches with dielectric materials. However, as advanced technology nodes shrink down and distances between adjacent devices continue to reduce, challenges may result in maintaining electrical isolations via the isolation elements. For example, isolation elements that extend deep into the wafer may provide lateral isolations in the top portion of the wafer, but not in the bottom portion of the wafer. Although silicon-on-insulator (SOI) technology provides increased isolation in certain applications, the insulator may not have a sufficient thickness to sustain certain applied voltages.

In some examples, multiple integrated circuits (ICs) described above may be coupled in different packages, such as via wire bonds or other types of couplings. These couplings can create a stress across the wafer and can damage dielectric layers above and/or in the wafer. Some of the ICs described above produce a significant amount of heat while operating, and there may be benefit if the heat is removed promptly. Various dielectrics, such as parylene, have a low thermal conductivity. Such dielectrics can reduce the rate of heat removal from the ICs.

This description provides various examples of ICs that include isolation elements and the processes of fabrication of such ICs. These various examples may be compatible with standard wafers and wafer processing flows, and thus provide economic efficiencies. The ICs in this description can create tunable high voltage isolation capability with dielectric isolation. In at least some examples, diode isolation is not utilized. The dielectric isolation can be useful for multiple process technologies, such as digital, analog, mixed signal, or memory. The ICs can include a support layer and/or a thermal conductive layer, which may provide mechanical support, increase heat transfer, and reduce moisture entering the ICs from the environment.

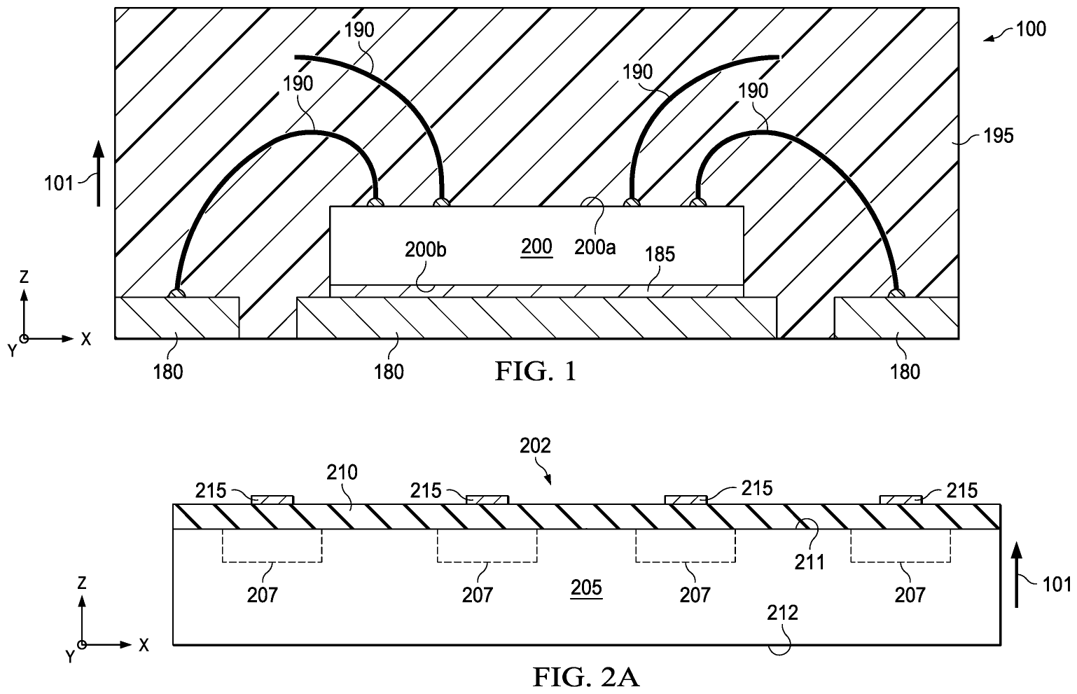

Various examples of the ICs are now described with reference to FIGS. 1-9. Specific components provided and arrangements thereof are provided as examples, and shall not be construed to be limiting. The description below may repeat reference numerals and/or letters in different examples for clarity, simplicity, and/or the ease of description. Such repetitions do not indicate any particular relationship among the various examples or components thereof.

FIG. 1 is a cross-sectional view of a system 100 including an IC 200, in various examples. In some examples, the system 100 may be implemented as part of devices such as central processing units (CPUs), graphic processing units (GPUs), memories, sensors, input/output devices, among others, useful for diverse applications, such as personal computers, smartphones, televisions, disc players, receivers, virtual artificial intelligence assistants, or any other system that includes multiple ICs. In FIG. 1, the x-axis and y-axis are horizontal axes orthogonal to each other and each define a direction in which a semiconductor substrate of the system 100 extends. For example, the x-axis and the y-axis collectively define an x-y plane and the top and bottom surfaces of the semiconductor substrate extend in the x-y plane. The z-axis is a vertical axis orthogonal to the x-y plane and represents the height dimension of the system 100. The same coordinate system will be referred to in descriptions that follow with respect to other figures. During fabrication, the IC 200 (or a precursor workpiece 202, described below with respect to other figures, that is processed to form the IC 200) may be flipped over in one or more steps. Accordingly, a bold arrow 101 shows the direction in which the IC 200 (or the workpiece 202) faces. For example, in FIG. 1, the IC 200 has a surface 200a (described as the “front” side) facing upwards, and a surface 200b (opposite to the surface 200a and described as the “back” side) facing downwards. Such a direction of the IC 200 is shown with the bold arrow 101 pointing upwards. In a subsequent figure showing an intermediate processing step, the workpiece 202 may have been flipped over, where the surface 200a faces downwards and the surface 200b faces upwards. Such an example scenario will be shown with the bold arrow 101 pointing downwards. The bold arrow 101 is for the ease of explanation and is not to be limiting. Moreover, spatially relative terms, such as “top,” “bottom,” “beneath,” “below,” “lower,” “above,” “upper,” “front,” “back,” and the like, are to assist the description of relative orientation or relationship between various elements or features (as shown in the figures) during certain fabrication steps. These spatially relative terms are not to limit the system 100 (or components thereof) in storage, transportation, or operation. For example, the device may be otherwise oriented (e.g., rotated by 90 degrees from what's shown in figures) where those spatially relative descriptors described herein may likewise be interpreted accordingly.

As shown in FIG. 1, the system 100 includes a package substrate 180, the IC 200, one or more attachments 185, one or more connections 190, and a package material 195. The package substrate 180 may have one or more portions. Examples of the package substrate 180 include a lead frame, a circuit board, or another chip or wafer. The attachments 185 connect the IC 200 to the package substrate 180 and can include a die attach material. The attachments 185 can include one or more suitable die attach materials, such as silver (Ag), glass, polymer, particle filled polymer, or an alloy. Although shown as wires, the connections 190 can alternatively be, or include, solder bumps, such as gold (Au) bumps, or any other suitable conductive connections. Moreover, although FIG. 1 shows four connections 190, any suitable alternative number of connections 190 may be included. The connections 190 can each connect different parts of the IC 200 to the same or different portions of package substrate 180. The package material 195 may be any suitable material that packages and protects the underlying IC 200 and peripheral features during fabrication, storage, transportation, or operation. For example, the package material 195 may include a plastic package material or a ceramic package material. Furthermore, additional parts of the system 100 (such as those connected to other ends of the connections 190) are omitted from FIG. 1 for simplicity.

FIG. 1 shows the system 100 as a wire bond package. However, other types of packages may be similarly implemented. Such packages may include solder-to-lead frame packages, wafer scale packages (e.g., with solder or Au bump), or combinations thereof. As described above, one or more die attach materials can be included in the same package with bump connection(s), wire bond connection(s), or both. The package can be coupled to a printed circuit board with a solder or bump connection. Examples of packages are described below herein and include surface mount, chip carrier, pin grid arrays, flat packages, small outline packages, chip-scale packages, ball grid array, small pin count IC packages, and multi-die packages.

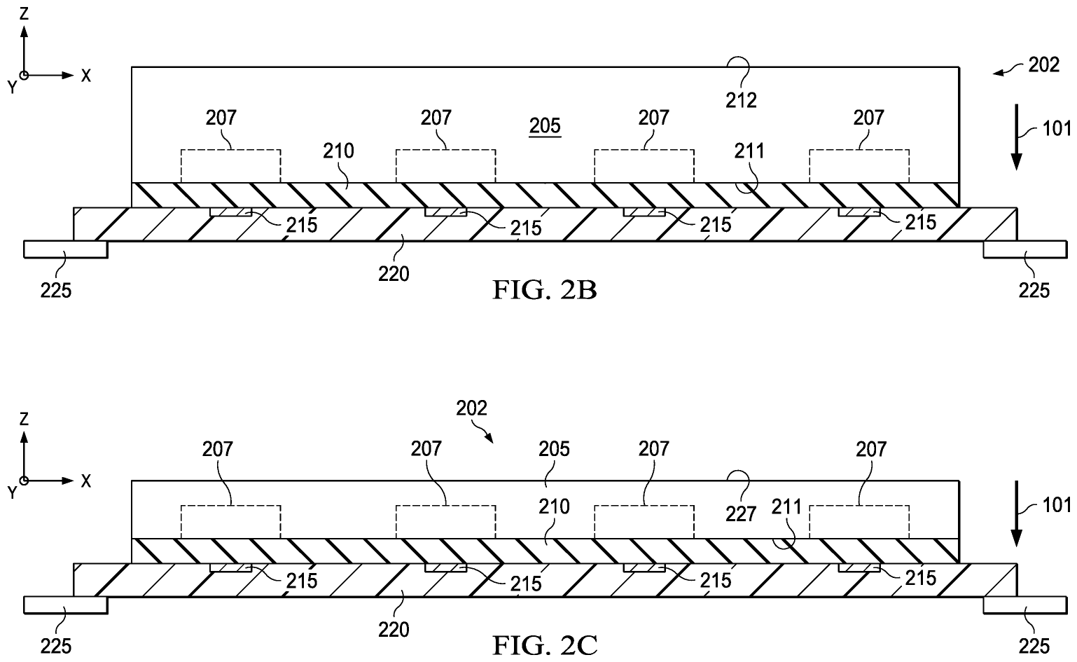

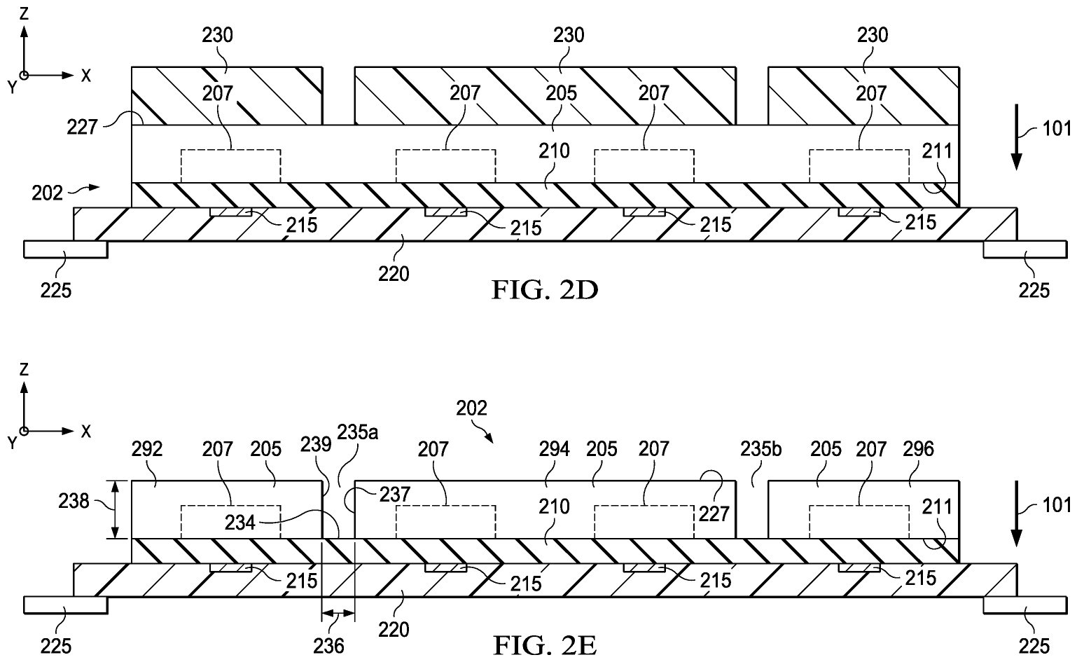

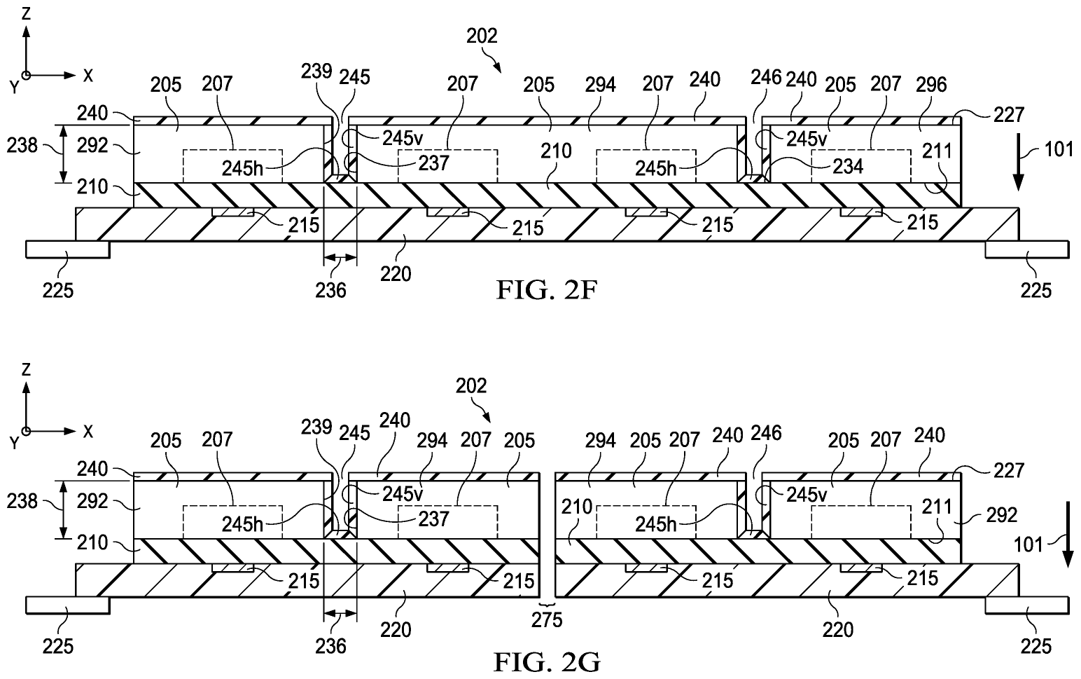

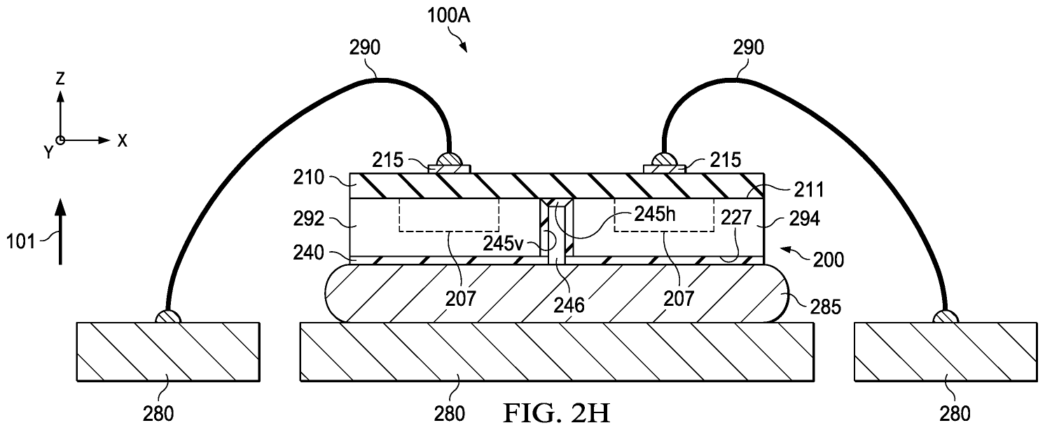

As described above, the system 100 includes IC 200, which is further described in detail below with respect to FIGS. 2A-2H, which may be collectively referred to as FIG. 2. FIGS. 2A-2H are cross-sectional views of the workpiece 202 at intermediate steps of the fabrication of the IC 200 at various processing stages of the fabrication in various examples of the description. In at least some examples, the workpiece 202 becomes the IC 200 at the end of a fabrication process, as described herein.

Referring to FIG. 2A, the workpiece 202 has various sub-devices 207 (e.g., diodes, capacitors, transistors, or combinations thereof) formed therein, which can be functional, sacrificial, or dummy. The identity, structure, or application of the sub-devices 207 are not limited herein. The sub-devices 207 may be formed according to any suitable fabrication processes. The workpiece 202 also includes a semiconductor wafer 205 on (or in) which the sub-devices 207 are formed. The semiconductor wafer 205 may include doped or undoped silicon and may include any other suitable features not specifically described herein.

The semiconductor wafer 205 has a frontside surface 211 between the semiconductor wafer 205 and the dielectric layer 210, and a backside surface 212 opposite to the frontside surface 211. The dielectric layer 210 can include various metal features formed therein. For example, metal lines may be formed from aluminum (Al) or copper (Cu), contact structures may be formed between a bottom metal line and active or passive sub-devices 207, and vias may be formed to connect the contact structures to the metal lines. For Al metallization, the vias may include tungsten (W). In some examples, the frontside surface 211 may be the surface on which processing is performed to form the sub-devices 207. Accordingly, the sub-devices 207 may be exposed on the frontside surface 211. In other examples, the sub-devices 207 may be embedded shallowly beneath the frontside surface 211. As shown in FIG. 2A, a bulk portion of the semiconductor wafer 205 is present between the back surface of the sub-devices 207 and the backside surface 212. As described below, the bulk portion of the semiconductor wafer 205 may be subsequently thinned or polished.

The dielectric layer 210 can include a dielectric material such as silicon oxide (SiO₂), aluminum oxide (Al₂O₃ or AlOₓ), silicon nitride (SiN), silicon oxynitride (SiON), silicon oxynitrocarbide (SiONC), silicon carbide (SiC), aluminum nitride (AlN), any other suitable materials, or combinations thereof. As shown in FIG. 2A, the dielectric layer 210 and the semiconductor wafer 205 share the frontside surface 211 as a common surface. Accordingly, the frontside surface 211 is also referred to as an “interface” between the dielectric layer 210 and the semiconductor wafer 205. Moreover, such relative arrangement of the layers is referred to as the dielectric layer 210 “interfacing with” the semiconductor wafer 205. The dielectric layer 210 can include dielectric materials and one or more metal layers. A top metal layer may be partially or completely exposed to form contact pads 215. In the example shown in FIG. 2A, the contact pads 215 are located on a front surface of the dielectric layer 210. The contact pads 215 connect to the connections 190 of FIG. 1 and can include metals such as Al or Cu.

Referring to FIG. 2B, the workpiece 202 is flipped upside down and placed on a first carrier. The first carrier may be any suitable wafer carrier and may include any suitable material, such as glass, silicon, polymer (e.g., epoxy), tape, frame, or combinations thereof. In FIG. 2B, the first carrier includes a tape 220 and a frame 225. As shown in FIG. 2B, the front surface of the dielectric layer 210 directly contacts the tape 220 and the backside surface 212 of the semiconductor wafer 205 is exposed for subsequent processing. As described above, such an arrangement is shown with the bold arrow 101 pointing downwards.

Referring to FIG. 2C, the thickness of the semiconductor wafer 205 is reduced along the z-direction from the backside surface 212. The reduction may be performed by polishing (e.g., chemical mechanical polishing), grinding, any other suitable methods, or combinations thereof. The semiconductor wafer 205 can be processed to have any suitable thickness. For example, after reducing the thickness in the z-direction, the semiconductor wafer 205 can have a thickness in the z-direction of about 20 micrometer (μm) to about 300 μm, about 20 μm to about 200 μm, or about 50 um to about 100 μm. If the thickness of the semiconductor wafer 205 is too small (e.g., less than about 0.1 μm), certain device features (such as the sub-devices 207) may be compromised during operation. If the thickness of the semiconductor wafer 205 is too large (e.g., greater than about 5,000 μm), benefit of the increased isolation may be offset by the extra processing and increased material cost. Following the reduction in thickness of the semiconductor wafer 205, the semiconductor wafer 205 (and the workpiece 202) has a new backside surface 227 exposed for subsequent processing.

Referring to FIG. 2D, a patterned mask layer 230 is formed on the backside surface 227 of the semiconductor wafer 205. The patterned mask layer 230 may be formed according to any suitable methods. For example, a continuous precursor layer (not shown) may be deposited onto the backside surface 227 of the semiconductor wafer 205 according to any suitable deposition methods (such as chemical vapor deposition (CVD), physical vapor deposition (PVD), atomic layer deposition (ALD), plasma-enhanced chemical vapor deposition (PECVD), etc.). The precursor layer can include semiconductor materials such as SiO₂, SiN, SiON, Al₂O₃, AlN, TiN, W, NiW, nickel-palladium (NiPd), titanium tungsten (TiW), Cu, Al, Ru, etc. A top of the precursor layer is then coated with a photoresist (e.g., by spray coating or spin coating). Portions of the photoresist are exposed to a light radiation and developed to form a patterned photoresist. Etching (e.g., a wet etching or dry etching) is subsequently performed to transfer the pattern of the patterned photoresist to the precursor layer, thereby forming the patterned mask layer 230. In other examples, the forming of the precursor layer may be omitted, and the patterned photoresist may instead serve the function of the patterned mask layer 230.

Referring to FIG. 2E, trenches 235 (e.g., a trench 235a, a trench 235b) are formed in the semiconductor wafer 205. The trenches 235 may be formed according to any suitable etching process to transfer the patterns of the patterned mask layer 230 onto the semiconductor wafer 205. In some examples, the semiconductor wafer 205 includes silicon (Si). In such examples, the etching process may include Bosch Si etch or silicon deep reactive ion etch process. A high-density plasma etch with a sidewall passivation etch may also be suitable for via or Si trench isolation etches. As shown in FIG. 2E, the etching process etches through the semiconductor wafer 205 such that the trenches 235 extend through the height dimension (e.g., the dimension along z-direction) of the semiconductor wafer 205 from the backside surface 227 to the frontside surface 211. After the trench formation, the semiconductor wafer 205 is divided into multiple wafer portions (e.g., wafer portions 292, 294, and 296) that are not laterally (e.g., along the x-direction) connected to each other. For example, the wafer portions 292 and 294 are formed on both sides of the trench 235a and isolated from each other. Also, sub-devices 207 of the wafer portions 292 and 294 are electrically decoupled from each other. As described elsewhere herein, such through-wafer trenches allow the formation of through-wafer isolation elements that provide isolation between various components, thereby increasing the overall functioning of the IC 200 over those fabricated with other approaches. The wafer portions 292, 294, and 296 are side by side with each other or juxtaposed with each other.

The dielectric layer 210 interfaces with the wafer portion 292, 294, and 296 each on the frontside surface 211. The trenches 235 each include a side surface 239 defined by the wafer portion 292 and a side surface 237 defined by the wafer portion 294. The trenches 235 also each have a front surface 234 defined by the dielectric layer 210. The front surface 234 extends along and is coplanar with the frontside surface 211 of the semiconductor wafer 205. The trench 235a has a depth 238 along the z-direction defined by the height dimension of the semiconductor wafer 205 (e.g., the distance between the frontside surface 211 and the backside surface 227). The trench 235a has a width 236 along the x-direction that is defined by the distance between the wafer portions 292 and 294. The depth 238 in the z-direction can be about 10 μm to about 100 μm, about 20 μm to about 100 μm, or about 20 μm to about 50 μm. The width 236 in the x-direction can be about 5 μm to about 50 μm, about 10 μm to about 50 μm, or about 10 μm to about 20 μm. If the width 236 is too small (e.g., less than about 0.1 μm), isolation between adjacent wafer portions 292, 294, and 296 may be insufficient to prevent leakage. If the width 236 is too large (e.g., greater than about 100 μm), benefits stemming from increased isolation may be offset by increased costs. The trench 235b is formed substantially similar to the trench 235a, but may have different height and width. In some examples, the trenches 235 have an aspect ratio of about 1:20 to about 1:2, about 1:15 to about 1:5, or about 1:12 to about 1:7. The aspect ratio of a feature herein is defined as the ratio of the feature dimension in the x-direction to the feature dimension in the z-direction. If the aspect ratio is too large (e.g., greater than about 100:1), the footprint of the trenches 235 may be high (e.g., impeding the down-scaling of the technology nodes). An aspect ratio that is too small (e.g., e.g., less than about 1:1000) can increase the difficulty in etching the trench 235a and filling the trench 235a (e.g., with a dielectric material). A narrower trench 235a impacts the isolation voltage and increases the difficulty in filling the trench 235a (e.g., with a dielectric material). One alternative to this tradeoff in isolation voltage can be multiple trenches which may increase thickness of a dielectric material filled in the trench 235a between voltage islands but may take up more horizontal area or footprint. An aspect ratio that is too large (e.g., greater than about 100:1) can have a smaller thickness of semiconductor wafer 205, which increases manufacturing difficulty to prevent mechanical failure. A semiconductor wafer 205 with a smaller thickness may also decrease the capacitance with materials (e.g., a dielectric material) to create capacitor. In some examples, an aspect ratio that is too large (e.g., greater than about 100:1) has a wider trench 235a, which makes mechanical structures above the trench 235a weaker.

Following the forming of the trenches 235, the patterned mask layer 230 is removed according to any suitable process. An ashing step or other cleaning steps may be performed to remove residue materials from the trenches 235 to prepare for the deposition of isolation dielectric materials therein.

Referring to FIG. 2F, an isolation dielectric material is deposited onto the workpiece 202. In some examples, the isolation dielectric material is deposited onto the backside surface 227, the side surfaces 237, 239, and the front surface 234. Accordingly, an isolation element is formed. The isolation element includes isolation segments 245 inside the trenches 235 and, optionally, extension portions 240 outside the trenches 235 and on backside surfaces 227. In the example shown in FIG. 2F, the isolation dielectric material does not entirely fill the trenches 235. The isolation segments 245 may each include vertical portions 245v on side surfaces 237 and 239, as well as horizontal portion 245h on the front surface 234 and connecting the vertical portions 245v. The vertical portions 245v each extend vertically from the front surface 234 of the trenches 235 to the height level of the backside surface 227. The horizontal portion 245h extends along the front surfaces 234 and between side surfaces of the vertical portions 245v. In some examples, the horizontal portion 245h has a thickness across the z-direction that is substantially similar to the thickness of the vertical portions 245v across the x-direction. For example, the isolation segment 245 includes a conformal layer of isolation dielectric material. The side surfaces of the vertical portions 245v as well as the surface of the horizontal portion 245h define a gap 246. In some examples, the gap 246 occupies a space that accounts for a percentage of the lateral dimension of the width 236 of the trenches 235 along the x-direction. In some examples, the percentage may be about 0.01% to about 99%, about 10% to about 90%, about 30% to about 70%. Presence of the gap 246 may depend on the width of the trench 235a and thickness of the isolation dielectric material. For example, if the trench 235a is about 10 μm wide and the isolation dielectric material is about 4 μm thick, a gap 246 may be present. In another example, the trench 235a is about 10 μm wide and about 10 μm thick isolation dielectric material is deposited in the trench 235a, and the gap 246 may not be present. In examples with similar ratios of thickness of isolation dielectric material to the width of the trench 235a, depending on the step overage, the isolation dielectric material may entirely fill the trench 235a. In such examples, thickness of the isolation dielectric material on the backside surface 227 of the semiconductor wafer 205 may be the same as the width of the trench 235a.

In the examples shown in FIG. 2, the isolation segment 245 has a “U” shaped profile with the vertical portions 245v each resembling a side arm of the “U” and the horizontal portion 245h resembling a bottom portion of the “U.” In some examples, the width of the trench 235a at the bottom of the trench 235a is narrower than the width at the top of the trench 235a, and the “U” shaped profile becomes more representative of a “V” shaped profile. This type of profile may make it easier to fill the trench 235a with the isolation dielectric material. The vertical portions 245v and the horizontal portion 245h include a same material and extend continuously from one to the other. In some examples, the gap 246 is preserved in subsequent processing and remains in the final IC 200. Such gaps 246 may increase the electrical isolation between the wafer portions 292 and 294, such as due to the lower dielectric constant of air as compared to other dielectric materials. In some examples, there is differential thermal expansion of the trench dielectric compared to the surroundings, and the gaps 246 may also reduce the stress applied.

In some examples not shown in FIG. 2F, the trenches 235 are entirely filled with the isolation dielectric material such that no gap 246 is formed. In such examples, the vertical portions 245v and horizontal portion 245h are merged together to form the isolation segment 245. In some circumstances, the merged isolation segment 245 may provide increased mechanical strength useful for certain applications of the IC 200. For example, if there are wire bond, solder, or bump bond pads inside the trenches 235, increased mechanical strength may mitigate damage from the electrical connection process.

As described above, extension portions 240 of the isolation dielectric material may have been formed on the backside surface 227. In some examples, a chemical-mechanical planarizing (CMP) operation is optionally conducted to remove the extension portion 240, thereby exposing the semiconductor wafer 205. In some examples, another isolation dielectric material is optionally deposited onto the exposed semiconductor wafer 205 (and on top of the isolation segment 245) to form a new extension portion 240. The new extension portion 240 may have a material that is the same as or different from that of the isolation segment 245. In some examples, the new extension portion 240 extends continuously between adjacent isolation segments 245. In some examples, the extension portion 240 remains and the isolation segment 245 is removed. In some examples, an isolation dielectric layer is formed over the extension portion 240 and on the side surfaces 237 and 239 and the front surface 234 of the trench 235a. The portion of the isolation dielectric layer over the extension portion 240 is removed by a mechanical process or CMP, stopping on the extension portion 240. Alternatively, the isolation segment 245 may be formed by un-patterned etching of the isolation segment 245 from the backside but remaining in the trench 235a, or a patterned etching of the isolation segment 245 where the isolation segment 245 has been removed from at least a portion of the backside.

As described above, the extension portion 240 extends from the backside surface 227 and away from the frontside surface 211. In some examples, a section of the extension portion 240 extends from the vertical portion 245v in a direction along the z-axis opposite to the frontside surface 211. The extension portion 240 interfaces with the wafer portion 292 and with the wafer portion 294, each on the backside surface 227. The extension portion 240 extends between two or more adjacent isolation segments 245. The extension portion 240 can have any suitable thickness in the z-direction and any suitable width in the x-direction. For example, the extension portion 240 has a thickness in the z-direction of about 1 μm to about 100 μm and a width in the x-direction of about 10 μm to about 10,000 μm. If the thickness and/or width is too small (e.g., less than about 0.1 μm), certain device features (such as increased isolation) may be compromised during operation. If the thickness and/or width is too large (e.g., greater than about 500 μm), benefit of the increased isolation may be offset by the extra processing and increased material cost. The extension portion 240 can have an aspect ratio equal to or greater than about 1:20, equal to or greater than about 1:1, equal to or greater than about 10:1, equal to or greater than about 100:1, or equal to or greater than about 1000:1. If the aspect ratio is too small (e.g., less than about 1:1000), the height of the extension portion 240 may be large (e.g., impeding scaling-down of the IC 200).

As described above, the extension portion 240 may be omitted (not shown in FIG. 2F). In such examples, the isolation element includes only the isolation segment 245, and the wafer portions 292 and 294 are exposed on their respective backside surfaces 227. In some examples, the isolation segment 245 has an aspect ratio of about 1:2 to about 1:10, about 1:3 to about 1:10, about 1:5 to about 1:10. If the aspect ratio is too large (e.g., greater than about 100:1), the electrical isolation across the isolation element may be insufficient for some applications. If the aspect ratio is too small (e.g., less than about 1:1000), the isolation element may be large (e.g., impeding scaling-down of the IC 200).

Although not specifically shown in FIG. 2F, a liner may be formed between the isolation element and the wafer portions 292, 294. For example, a liner may be formed between the vertical portions 245v and the side surfaces 239 and 237, and between the horizontal portions 245h and the dielectric layer 210. Also, the liner may be formed between the extension portion 240 and the backside surface 227. Also, the liner may be formed beneath the isolation element on other surfaces of the trench 235a not shown in FIG. 2F (e.g., a surface of the trench 235a parallel to the x-z plane).

The isolation dielectric material can include a polymer dielectric material, an inorganic dielectric material, or combinations thereof. The polymer dielectric material can include parylene. In some examples, the polymer dielectric material is selected from the group consisting of parylene-F, parylene-HTC, parylene-AF4, parylene C, parylene D, polytetrafluoroethylene (PTFE), polyimide, poly(p-phenylene-2,6-benzobisoxazole) (PBO), benzocyclobutene (BCB), Teflon, polyimide, and combinations thereof. The inorganic dielectric material can include SiO₂, SiON, SiN, SiONC, SiC, AlN, Al₂O₃, AlOₓ, boron nitride (BN), boron carbon nitride (BCN), spin-on-glass (SOG), hydrogen silsesquioxane (HSQ), diamond (e.g., carbon), or combinations thereof.

Referring to FIG. 2G, the workpiece 202 is cut to form a severance 275 across the height dimensions of the semiconductor wafer 205, the dielectric layer 210, the tape 220, as well as features thereon. The cutting forms the IC 200 by severing the IC 200 from adjacent devices of the workpiece 202. In some examples, fabrication of the IC 200 is concluded following cutting of the workpiece 202. In other examples, any suitable method can be useful to make the IC 200, which is contemplated by this description. An attachment 285 is then formed on top of the IC 200. The IC 200 is then separated from the tape 220, flipped upside down, and attached to a package substrate 280. The attachment 285 and the package substrate 280 are to be shown and described further in FIG. 2H.

FIG. 2H is a cross-sectional view of a system 100A including the IC 200. In the example of FIG. 2H, the attachment 285 bonds directly onto the extension portion 240 such that an interface is formed therebetween. In examples in which the extension portion 240 is omitted, the attachment 285 directly bonds to the backside surface 227 of the wafer portions 292, 294. Also, in the example of FIG. 2H, a gap 246 remains within the IC 200 at this fabrication stage and the bonding of the attachment 285 does not fill the gap 246. Accordingly, the gap 246 persists in the system 100A. Thus, the attachment 285 has a portion of its surface exposed within the gap 246. As described above, the presence of the gap 246 in the IC 200 may increase isolation in comparison to examples that lack the gap 246, such as examples in which the gap 246 has been filled. In some examples, the isolation segment 245 has a relatively low thermal conductivity and the extension portion 240 has a relatively higher thermal conductivity, which may yield a relatively higher thermal conductivity from the backside of the IC 200, as shown by FIG. 2H.

The system 100A may be similar to the system 100, described above with respect to FIG. 1. For example, the system 100A includes the package substrate 280 (similar to the package substrate 180 of FIG. 1), the IC 200, the attachment 285 (similar to the attachment 185 of FIG. 1), and the connections 290 (similar to the connections 190 of FIG. 1). Although not specifically shown in FIG. 2H, a package material (similar to the package material 195 of FIG. 1) may be included.

As described above, the wafer portion 292 can include one or more of the sub-devices 207 configured for a first application to receive a first voltage V1. The wafer portion 294 can include another one or more of the sub-devices 207 configured for a same or different application and to receive a second voltage V2. In some examples, the first voltage and the second voltage have a voltage difference (D=|V1−V2|) that is equal to or greater than a threshold percentage of the smaller voltage of V1 and V2. In some examples, the threshold percentage is about 25%, about 50%, about 75%, or about 100%. In other examples, the threshold percentage is about 200%, about 300%, about 400%, or about 500%.

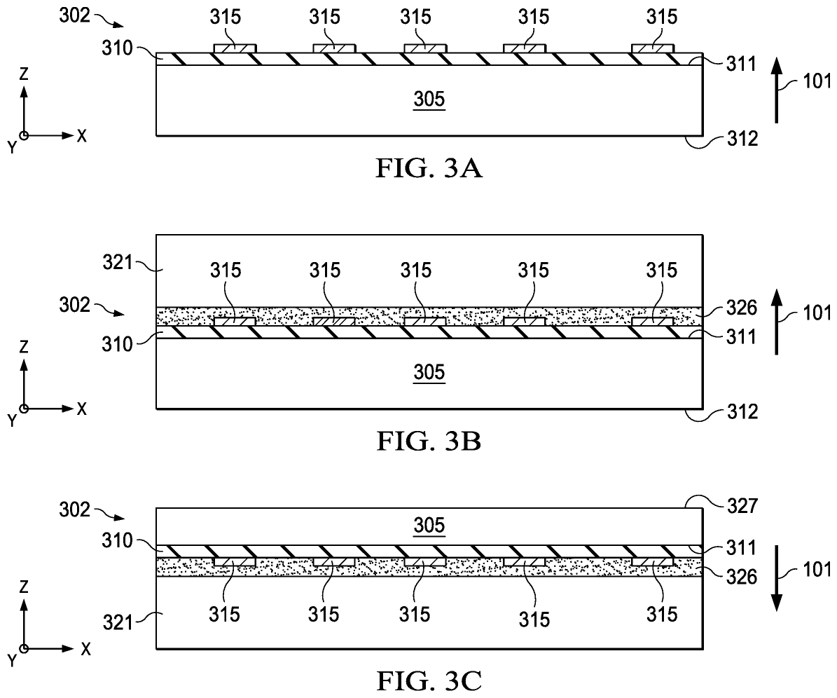

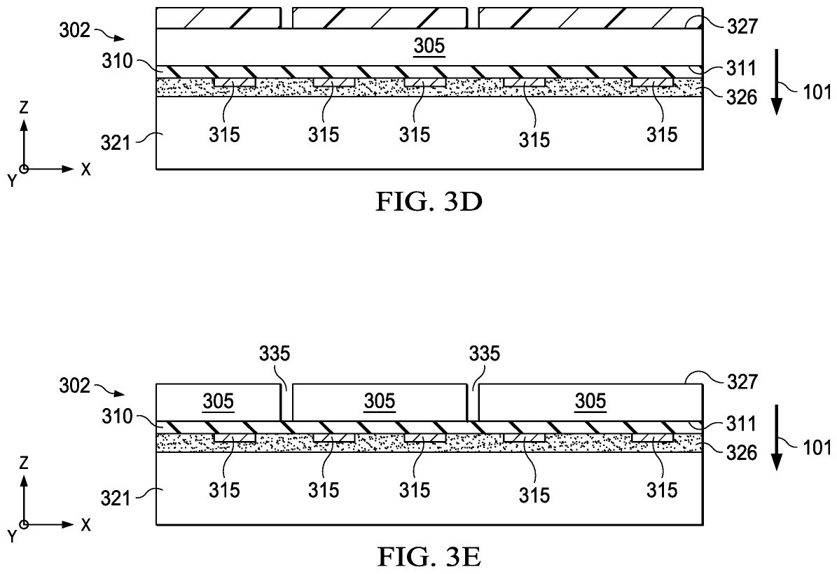

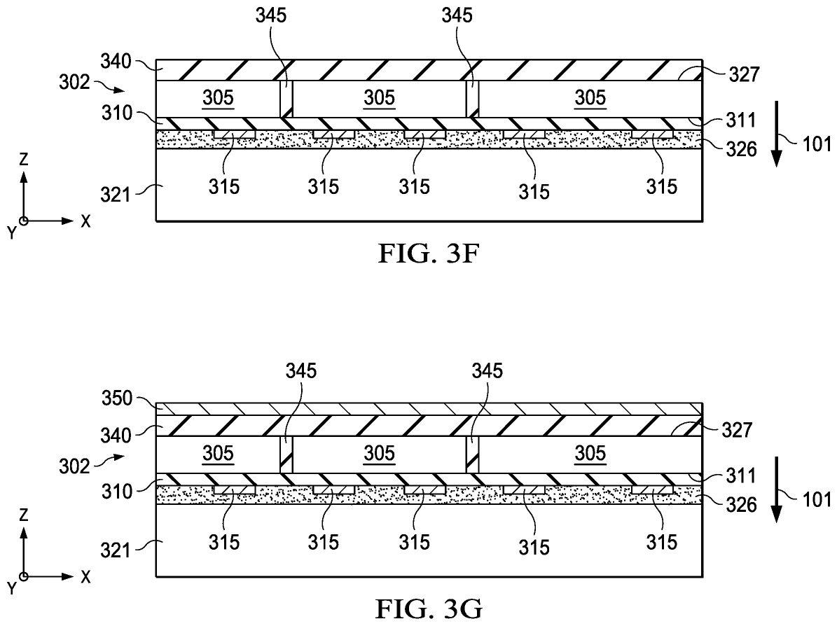

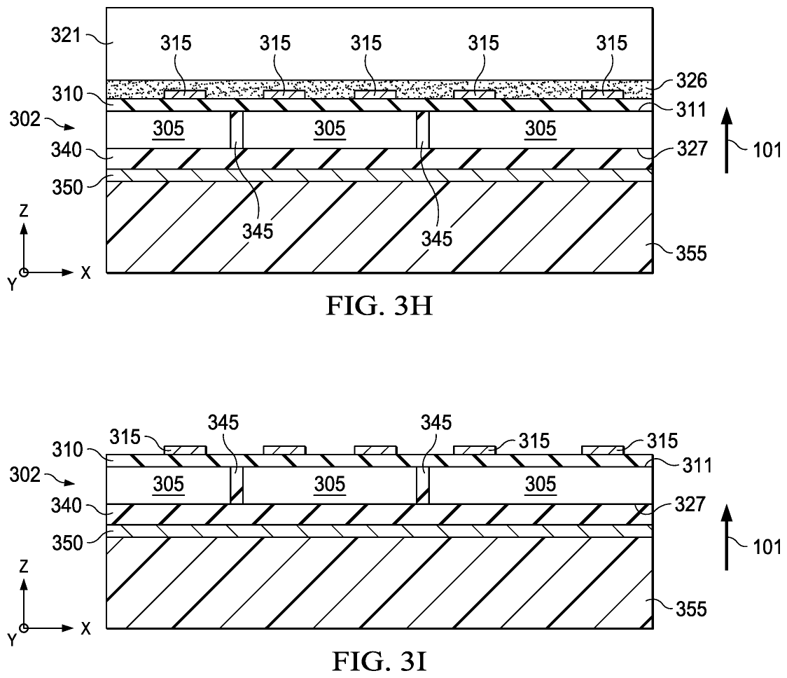

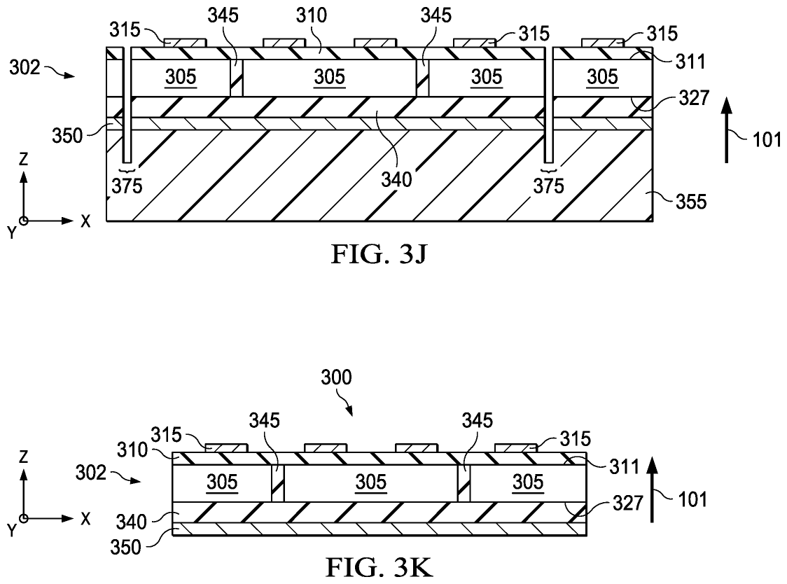

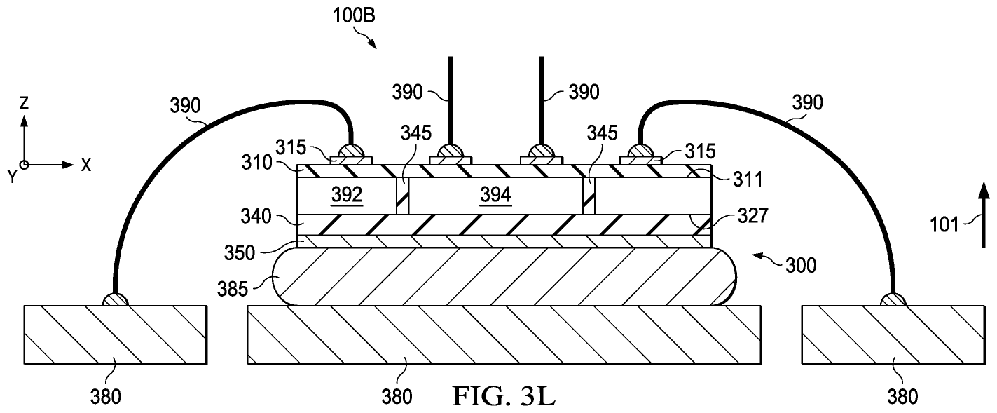

FIG. 2 provides an example structure for fabricating the IC 200. However, an IC may be fabricated according to another structure, such as shown in FIGS. 3A-3L, which may be collectively referred to as FIG. 3. FIGS. 3A-3L are cross sectional views of the workpiece 302 at various processing stages of the fabrication of the IC 300, in various examples. The IC 300 (or workpiece 302) generally resembles the IC 200 (or workpiece 202), as described above with respect to FIGS. 2A-2H. For example, the IC 300 includes a semiconductor wafer 305 similar to the semiconductor wafer 205 of IC 200, dielectric layer 310 similar to the dielectric layer 210 of IC 200, and contact pads 315 similar to the contact pads 215 of IC 200. The semiconductor wafer 305 has a frontside surface 311 and a backside surface 312, similar to the frontside surface 211 and backside surface 212 of the semiconductor wafer 205, respectively. The dielectric layer 310 can include dielectrics and one or more layers of metallization similar to that described in FIGS. 2A-2E. Similar to the workpiece 202 progressing through a fabrication process as shown in FIGS. 2A-2E, the workpiece 302 undergoes these modifications in FIGS. 3A-3E. However, referring to FIG. 3B, unlike workpiece 202 which is placed on a first carrier including a tape 220 and a frame 225, the workpiece 302 is placed on a first carrier including a glass, ceramic, or carrier wafer 321 (e.g., a Si wafer) and a wafer bond 326 (e.g., a polymeric temporary bond layer). The carrier wafer 321 can also include silicon, an organic material, metal or a ceramic. The carrier wafer 321 and wafer bond 326 can be transparent, thus the frontside surface 311 can be observed for alignment of the backside features to the frontside. Alternatively, the semiconductor wafer 305 is transparent or semi-transparent. The wafer bond 326 is formed between the carrier wafer 321 and the dielectric layer 310, and interfaces with the dielectric layer 310 and the contact pads 315. The wafer bond 326 can provide temporary adhesion but can be removed later. A thermal budget (e.g., an upper limit of temperatures that an element can be used) of the wafer bond 326 can be 300° C. or up to 400° C., and a higher thermal budget might be possible with future improvements.

Referring to FIG. 3C, the thickness of semiconductor wafer 305 in the z-direction can be reduced (e.g., by grinding or polishing) to any suitable thickness in the z-direction. The thickness roughly can be controlled by the removal or additional polish step. In some examples, the semiconductor wafer 305 has a smaller thickness in the z-direction, compared to the semiconductor wafer 205 in FIG. 2C. For example, the semiconductor wafer 305 can have a thickness in the z-direction of about 20 μm to about 300 μm, about 50 μm to about 200 μm, or about 50 μm to about 100 μm. If the thickness is too small (e.g., less than about 0.1 μm), certain device features (such as the sub-devices 307, which are not shown here but are similar to the sub-devices 207 described above) may be compromised during operation. If the thickness is too large (e.g., greater than about 5,000 μm), benefit of the increased isolation may be offset by the extra processing and increased material cost.

Referring to FIGS. 3C-3F, the workpiece 302 undergoes processing similar to those described above with respect to FIGS. 2C-2F. For example, in FIG. 3D the layer 330 can be the patterned resist or polymer that masks the surface of the semiconductor wafer 305 like Si. In FIG. 3E, the semiconductor wafer 305 has been etched stopping on the dielectric such as SiO₂ on the frontside surface next to the Si. This is followed by removal of the patterned polymer by an ash or wet strip process. For example, at the processing stage of FIG. 3F, an isolation dielectric material is deposited into the trenches 335 and on backside surfaces 327, thereby forming the isolation segment 345 and the extension portions 340. In the example shown in FIG. 3F, the isolation segment 345 fills the trenches 335 without leaving a gap. However, in alternative examples, a gap similar to the gap 246 of FIG. 2F may be formed. In some examples, it is possible to add an additional step to selectively remove the isolation dielectric from the backside. This can be done by adding another polymer with resist and then removal of the dielectric. In such cases, extra materials can be removed by wet strip or an ash process. Another suitable technique may be direct removal by a laser like process where the laser illumination directly corresponds to where the isolation dielectric is removed.

Referring to FIG. 3G, a support layer 350 (e.g., a metal layer, a dielectric layer) is formed on the back surface of the extension portion 340. In some examples, the support layer 350 increases structural integrity of the IC 300. In some examples, the support layer 350 also functions as a moisture barrier to the layer(s) underneath (e.g., the extension portion 340). The support layer 350 may be formed according to any suitable process. In some examples, the support layer 350 directly interfaces with and extends along the back surface of the extension portion 340. The support layer 350 can have any suitable thickness in the z-direction and any suitable width in the x-direction. For example, the support layer 350 can have a thickness of about 1 μm to about 50 μm and a width of about 1 μm to about 10,000 μm. If the thickness and/or width is too small (e.g., less than about 0.1 μm), certain device features (such as increased mechanical supporting) may be compromised during operation. If the thickness and/or width is too large (e.g., greater than about 1,000,000 μm), benefit of the increased isolation may be offset by the extra processing and increased material cost. The support layer 350 can have an aspect ratio greater than about 10:1, greater than about 100:1, greater than about 1000:1, etc. If the aspect ratio is too small (e.g., less than about 1:100), the height of the support layer 350 may be large (e.g., impeding scaling-down of the IC 300).

Some examples of materials suitable for the support layer 350 include TiW, W, titanium (Ti), TiN, Al, Cu, tantalum (Ta), tantalum nitride (TaN), SiO₂, SiON, SiN, silicon carbonitride (SiCN), AlN, Al₂O₃, BN, carbon such diamond, and the like. In some examples, the dielectric layer 310 is referred to as a first dielectric layer 310. The support layer 350 can include one or more sublayers (not shown), such as a metal layer, a second dielectric layer, a bonding layer, a diffusion barrier (also referred to as adhesion barrier), a polarization dielectric layer, or combinations thereof. These sublayers of the support layer 350 can have any suitable thicknesses in the z-direction and any suitable widths in the x-direction. For example, the metal layer, the second dielectric layer, the bonding layer, the polarization dielectric layer, and the diffusion barrier can have thicknesses in the z-direction of about 1 μm to about 200 μm, about 1 μm to about 200 μm, about 1 μm to about 300 μm, and about 1 μm to about 200 μm, respectively. The sublayers of the support layer 350 can be arranged in any suitable sequence. In an example, from the front to the back, the sequence can be the bonding layer, the second dielectric layer, the diffusion barrier, and the metal layer.

The metal layer can include any suitable metal, such as Al, Cu (e.g., electroplated Cu), Ti, TixAly alloy, titanium nitride (TiN), Ag, W, TiW, molybdenum (Mo), steel, silver-palladium (Ag—Pd) based alloys, and combinations thereof. Depositing the metal layer may be performed according to any currently or later developed process(es). For example, depositing Al based alloys can include sputter depositing, pattern etching, and cleaning. Depositing Cu and Ag—Pd based alloys can include seed/barrier depositing, mask layer patterning, electroplating, and removing the mask layer and seed/barrier. The second dielectric layer can include any suitable dielectrics, such as SiO₂, SiON, SiN, SiONC, SiC, AlN, Al₂O₃, AlOₓ, glass, ceramic, diamond like carbon, polycrystalline-Si, BN, and combinations thereof. In some examples, the bonding layer includes glass, epoxy, materials with coefficient of thermal expansion (CTE) control, such as ceramic embedded polymers, or combinations thereof. The diffusion barrier can include any suitable materials such as Ti, TiN, titanium tungsten (TiW), Ta, TaN, titanium silicon nitride (TiSiN), tantalum silicon nitride (TaSiN), titanium aluminum nitride (TiAlN), nickel (Ni), nickel tungsten (NiW), cobalt (Co), cobalt tungsten (CoW), Ruthenium (Ru), and combinations thereof. In various examples, the polarization dielectric layer includes any suitable material, such as polyimide, spin-on-glass (SOG), Teflon, silicone, other polarization dielectric materials, and combinations thereof.

In some examples, the support layer 350 provides mechanical support to the extension portion 340, the isolation segment 345, and other parts of the IC 300. Mechanical and thermal stresses can exist at the connections (e.g., contact pad 315), at the dielectric layer 310, and/or across the isolation element. These stresses can be from package materials, connections, thermal expansion of various parts in a package, or other sources. Such stresses can damage various parts in the IC 300. Mechanical support provided by the support layer 350 can reduce the damages that may otherwise be caused by the stresses.

In some examples, the support layer 350 provides bonding of the IC 300 to the package substrate 380 (such as a lead frame or a personal computer board). For example, the support layer 350 can increase adhesion of the IC 300 to the attachment 385 and/or other parts in a package.

Referring to FIG. 3H, the workpiece 302 may be flipped and placed on a second carrier 355. The second carrier 355 can include any suitable wafer carrier, such as glass, silicon, polymer (e.g., epoxy), tape, frame, or combinations thereof.

Referring to FIG. 3I, the first carrier may be removed from the workpiece 302 according to any currently or later developed process(es).

Referring to FIG. 3J, the workpiece 302 may be cut to form a severance 375, thereby severing IC 300 from adjacent devices to form the IC 300. In some examples, fabrication of the IC 300 is concluded following cutting of the workpiece 302. FIG. 3K shows the IC 300 that is ready for subsequent incorporation into a system. In other examples, any suitable method can be useful to make the IC 300, which is contemplated by this description.

FIG. 3L is a cross-sectional view of a system 100B including the IC 300. Similar to the system 100 in FIG. 1 and the system 100A in FIG. 2H, the system 100B includes a package substrate 380, an attachment 385, and connections 390, each similar to the corresponding parts in FIGS. 1 and 2H, respectively, as well as the IC 300. Although not specifically shown in FIG. 3L, the wafer portions 392 and 394 can include one or more sub-devices 307 similar to the sub-devices 207, described above. The isolation elements provided in the IC 300 provide increased isolation between adjacent wafer portions 392 and 394, while also increasing structural integrity of the IC 300. The package substrate 380 (such as a lead frame) may include a printed circuit board to increase the flexibility of the system 100B to include more ICs or more passive components such as diodes, resistors, capacitors or inductors.

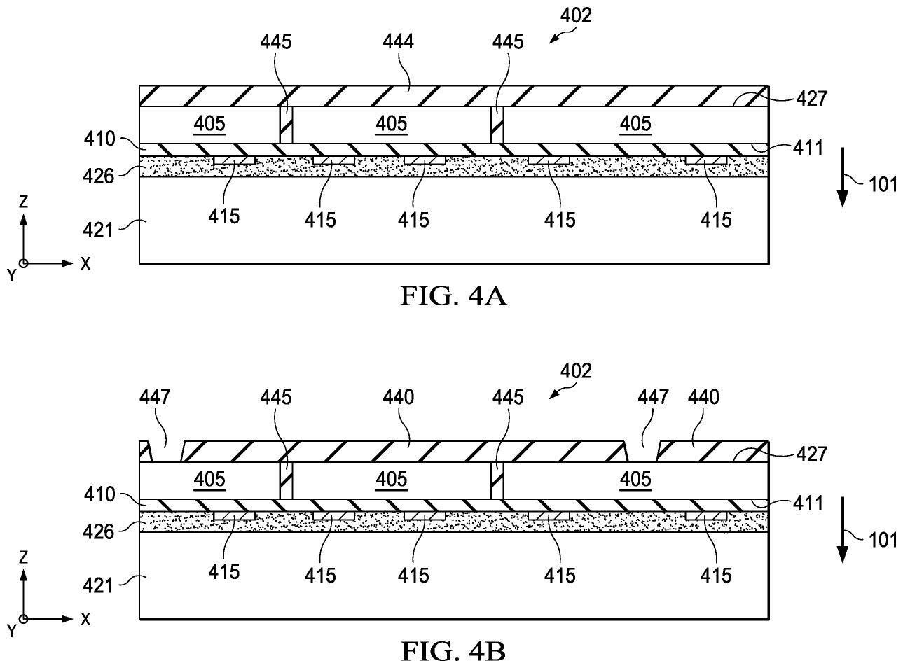

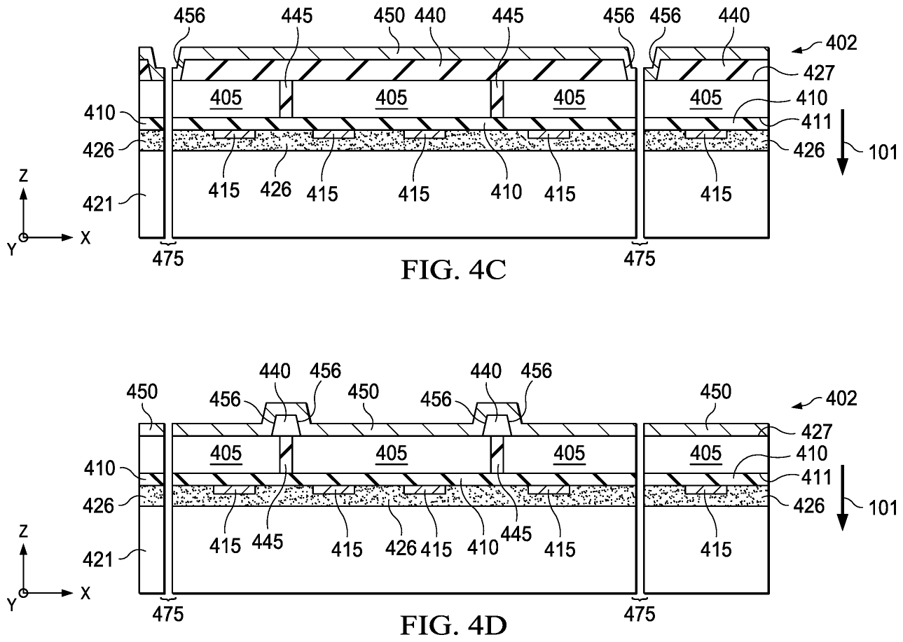

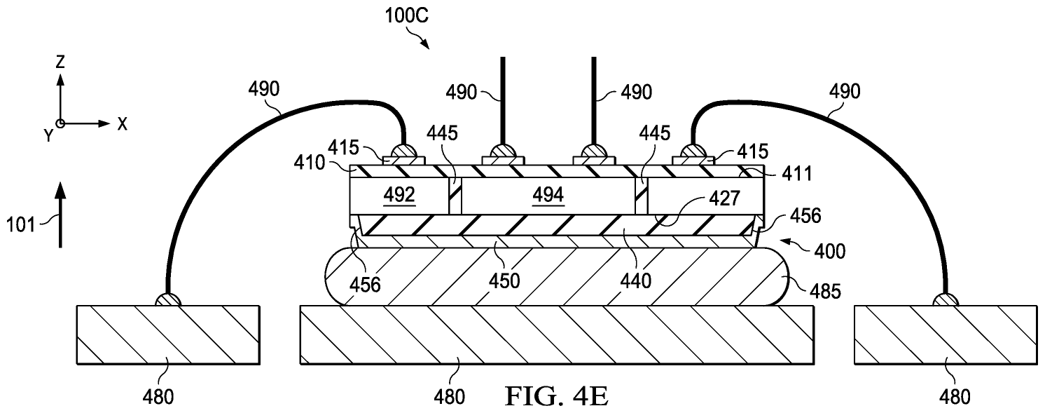

FIG. 3 provides an example structure for fabricating the IC 300. However, an IC may be fabricated according to another structure, such as shown in FIGS. 4A-4E, which may be collectively referred to as FIG. 4. FIGS. 4A-4E are cross sectional views of the workpiece 402 at various processing stages of the fabrication of the IC 400, in various examples. The IC 400 (or the workpiece 402) generally resemble the IC 300 (or the workpiece 302), as described above with respect to FIGS. 3A-3L, with the exceptions as described as follows. For example, the IC 400 includes a semiconductor wafer 405 similar to the semiconductor wafer 305 of IC 300, dielectric layer 410 similar to the dielectric layer 310 of IC 300, and contact pads 415 similar to the contact pads 315 of IC 300. The semiconductor wafer 405 has a frontside surface 411 and a backside surface 412, similar to the frontside surface 311 and backside surface 312 of the semiconductor wafer 305, respectively. Similar to the workpiece 302 progressing through a fabrication process as shown in FIGS. 3A-3F, the workpiece 402 undergoes these modifications and FIG. 4A shows the workpiece 402 similar to the workpiece 302 in FIG. 3F. However, a precursor extension portion 444 in FIG. 4A corresponds to extension portion 340 in FIG. 3F. Referring to FIG. 4B, at least a portion of the precursor extension portion 444 is patterned and etched with any suitable methods, such as direct laser removal or photolithography and etching. In some examples, the precursor extension portion 444 is etched, ashed, and cleaned. Following patterning and etching, at least a portion of the precursor extension portion 444 is removed to form a shallow trench 447. The shallow trench 447 can interface with the semiconductor wafer 405 at the backside surface 427 of the semiconductor wafer 405. The remaining of the precursor extension portion 444 becomes an extension portion 440. In some examples, the shallow trench 447 can interface with the extension portion 440 at a side surface of the extension portion 440. In some examples, the extension portion 440 and the isolation segment 445 collectively form the isolation element.

Referring to FIG. 4C, a support layer 450 (e.g., a metal layer, a dielectric layer) is deposited on the back and side surfaces of the extension portion 440 and on the backside surface 427 of the semiconductor wafer 405. The deposition may be performed according to any suitable currently or later developed process(es). The support layer 450 generally resembles the support layer 350, with the exceptions described below. In some examples, the support layer 450 directly interfaces with and extends along the back and side surfaces of the extension portion 440. In some examples, the support layer 450 directly interfaces with the backside surface 427 of the semiconductor wafer 405. An interface 456 of the support layer 450 and the extension portion 440 can intersect with the backside surface 427. The extension portion 440 can have any suitable thickness in the z-direction and any suitable average width in the x-direction. In an example, the extension portion 440 has a thickness in the z-direction of about 1 μm to about 100 μm and an average width in the x-direction of about 1 μm to about 1,000 μm. As shown in FIG. 4D, a larger portion of the precursor extension portion 444 is removed compared to FIGS. 4B-4C. In such examples, the support layer 450 can include dielectric materials including SiO₂, SiON, SiN, SiONC, SiC, AlN, Al₂O₃, AlOₓ, glass, ceramic, diamond like carbon, polycrystalline-Si, BN, or combinations thereof. The extension portion 440 can have a thickness in the z-direction of about 1 μm to about 100 μm and an average width in the x-direction of about 1 μm to about 900 μm. If the thickness and/or width is too small (e.g., less than about 0.1 μm), certain device features (such as increased isolation) may be compromised during operation. If the thickness and/or width is too large (e.g., greater than about 10,000 μm), benefit of the increased isolation may be offset by the extra processing and increased material cost. In some examples, the cross section of the extension portion 440 has any suitable shape, such as square, rectangle, or trapezoid.

The support layer 450 can include one or more sublayers similar to the support layer 350, as described above.

After deposition of the support layer 450, the workpiece 402 may be processed and undergo modifications similar to the workpiece 302 as shown in FIGS. 3H-3K, as described above. In the examples shown in FIGS. 4C-4D, the severance 475 can be through the shallow trenches 447. In some examples, fabrication of the IC 400 is concluded following severing of the workpiece 402. In other examples, any suitable method can be useful to make the IC 400, which is contemplated by this description.

FIG. 4E is a cross-sectional view of a system 100C including the IC 400. Similar to the system 100 in FIG. 1, the system 100A in FIG. 2H, and the system 100B in FIG. 3L, the system 100C includes a package substrate 480, an attachment 485, and connections 490, each similar to the corresponding parts in FIGS. 1, 2H and 3L, respectively, as well as the IC 400. Although not specifically shown in FIG. 4E, the wafer portions 492 and 494 can include different circuits or sub devices similar to the sub-devices 207, described above. The isolation elements provided in FIG. 4E provide increased isolation between adjacent wafer portions 492 and 494, while also increasing structural integrity of the IC 400.

In some examples, the support layer 450 provides protection for the isolation element (e.g., the extension portion 440) from moisture. The support layer 450 can include a moisture resistant material and/or a thin layer of a moisture resistant material. As shown in FIGS. 4C-4E, the support layer 450 can directly interface with and extend along the back and side surfaces of the extension portion 440, and the interface 456 of the support layer 450 and the extension portion 440 can intersect with the backside surface 427. Therefore, the back surface and side surfaces of the extension portion 440 are covered by the support layer 450. In such examples, the support layer 450 can prevent water from entering the extension portion 440.

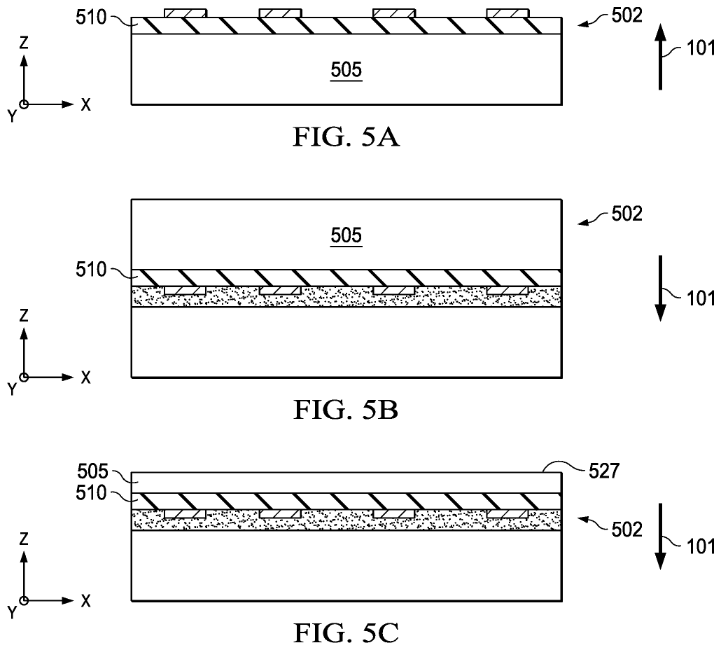

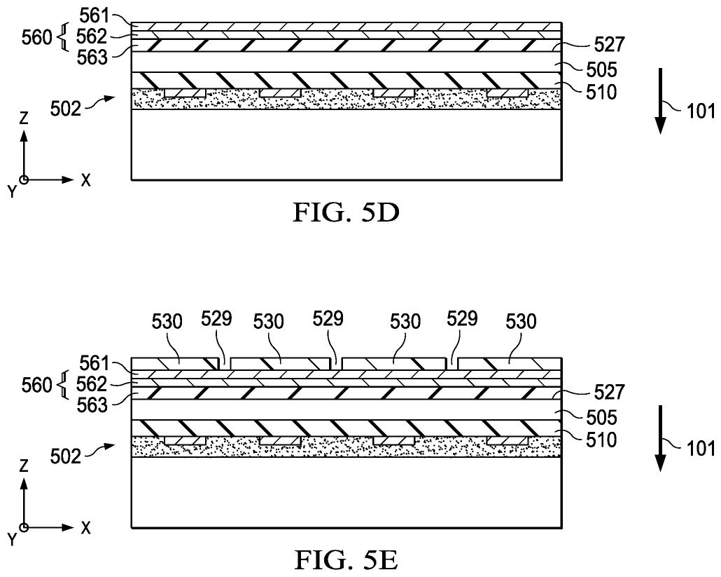

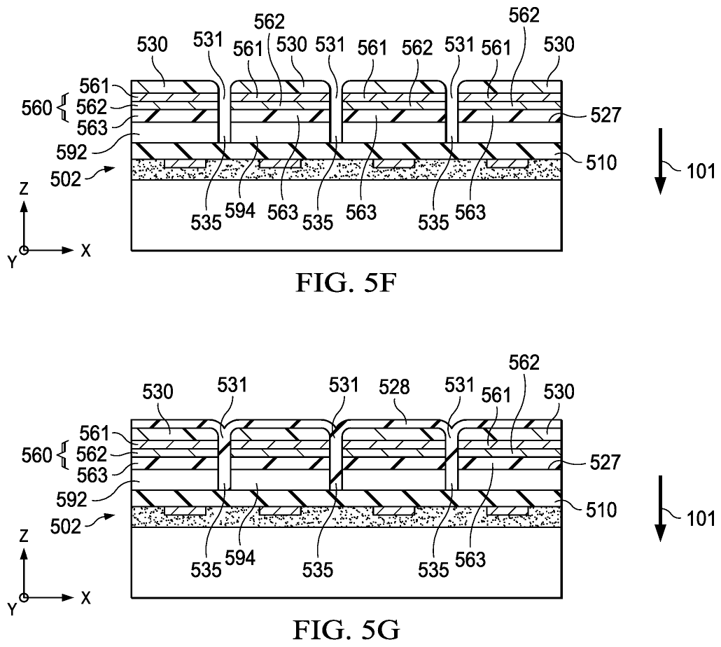

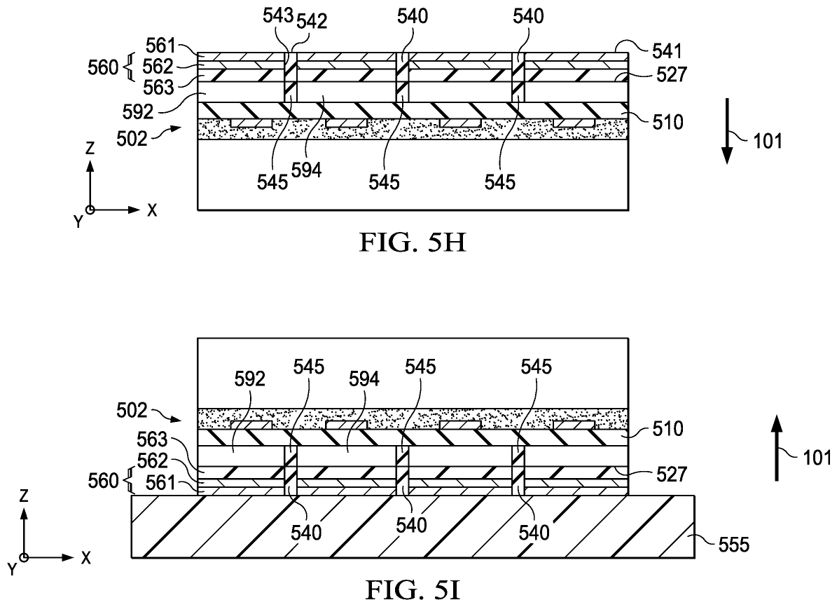

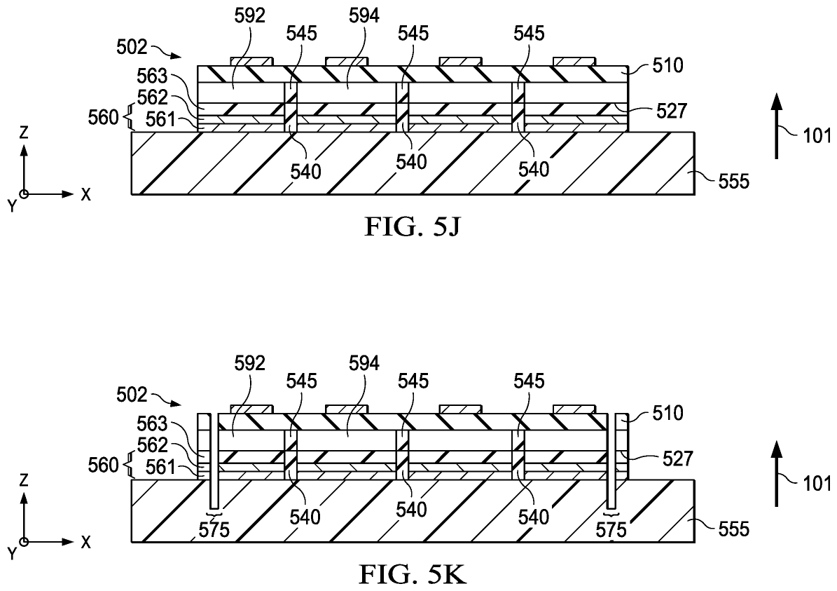

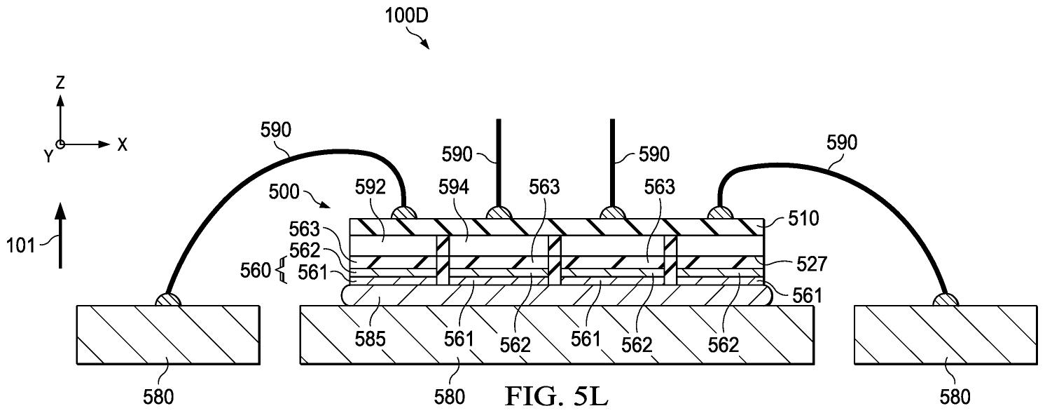

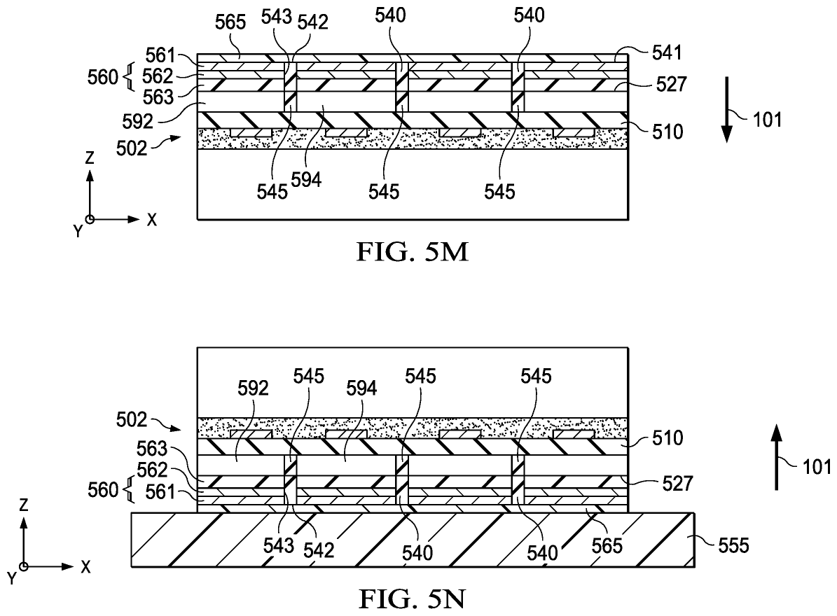

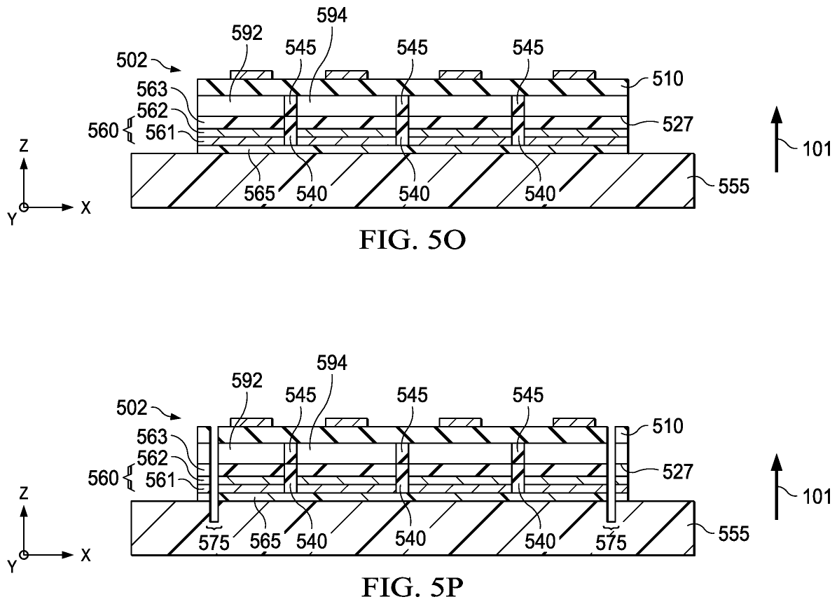

FIG. 4 provides an example structure for fabricating the IC 400. However, an IC may be fabricated according to another structure, such as shown in FIGS. 5A-5P, which may be collectively referred to as FIG. 5. FIGS. 5A-5P are cross sectional views of the workpiece 502 at various processing stages of the fabrication of the IC 500, in various examples. The IC 500 (or the workpiece 502) generally resemble the IC 300 (or the workpiece 302), as described above with respect to FIGS. 3A-3L, with the exceptions as described as follows.

Similar to the workpiece 302 progressing through a fabrication process shown in FIGS. 3A-3C, the workpiece 502 undergoes these modifications in FIGS. 5A-5C. Referring to FIG. 5D, a thermal conductive layer 560 is deposited onto the workpiece 502. In some examples, depositing the thermal conductive layer 560 is on the backside surface 527 of the semiconductor wafer 505. The deposition can include any suitable currently or later developed process(s). In some examples, the thermal conductive layer 560 directly interfaces with and extends along the backside surface 527 of the semiconductor wafer 505. In some examples, the dielectric layer 510 is also referred to as a first dielectric layer 510. In some examples, the thermal conductive layer 560 includes one or more sublayers, such as a third dielectric layer 563, a diffusion barrier 562, and a metal layer 561 as shown in FIG. 5D. The sublayers of the thermal conductive layer 560 can include the third dielectric layer 563, a polarization dielectric layer, or a combination thereof. In some examples, the sublayers of the thermal conductive layer 560 further include a metal layer, a diffusion barrier, or a combination thereof. These sublayers of the thermal conductive layer 560 can have any suitable thicknesses in the z-direction and any suitable widths in the x-direction. For example, the metal layer, the third dielectric layer, the diffusion barrier, and the polarization dielectric layer can have thicknesses in the z-direction of about 1 μm to about 200 μm, about 1 μm to about 200 μm, about 1 μm to about 300 μm, and about 1 μm to about 200 μm, respectively. Usually, the third dielectric layer or the polarization dielectric layer directly interfaces with and extends along the backside surface 527. The sublayers of the thermal conductive layer 560 can be arranged in any suitable sequence. In an example, from the front to the back, the sequence can be the third dielectric layer 563, the diffusion barrier 562, and the metal layer 561 as shown in FIG. 5D.

The metal layer 561 can include any suitable metal similar to the metal layer of the support layer 350, as described above, such as Al, Cu (e.g., electroplated Cu), Ag, W, Mo, steel, Ag—Pd based alloys, Ti, TiW, Co, TiAl, TiN, Ta, TaN, and combinations thereof. In some examples, the third dielectric layer 563 has a thermal conductivity equal to or greater than that of the isolation dielectric material. Third dielectric layer 563 can provide isolation from the backside of the device after the isolation dielectric is removed. The third dielectric layer 563 can also have breakdown voltage varied to voltage rating, thus the backside of the semiconductor wafer 505 does not provide a breakdown path. The third dielectric layer 563 can include any suitable dielectrics similar to the second dielectric layer of the support layer 350, as described above, such as SiO₂, SiON, SiN, SiONC, SiC, AlN, Al₂O₃, AlOₓ, glass, ceramic, diamond like carbon, polycrystalline-Si, BN, and combinations thereof. The third dielectric layer 563 may be deposited according to any currently or later developed process(es) such as physical vapor deposition (PVD) or plasma-enhanced chemical vapor deposition (PECVD). The third dielectric layer 563 can be deposited at temperatures compatible with a wafer support system (e.g., tape or temporary bonding material) of the IC 500, as described herein. Most tape systems have a limited thermal budget, such as about 100° C. or higher. The temporary bond materials may allow up to an about 300° C. thermal budget, but some temporary bond materials may allow up to about 400° C. or higher. In some examples, the polarization dielectric layer includes any suitable material similar to the polarization dielectric layer of the support layer 350, as described above, such as polyimide, spin-on-glass (SOG), Teflon, other polarization dielectric materials, and combinations thereof. The diffusion barrier can include any suitable materials such as Ti, TiN, TiW, Co, Ru, Ta, TaN, W, NiW, and combinations thereof, or dielectric materials such as SiO₂, SiON, SiN, SiONC, SiC, AlN, Al₂O₃, AlOₓ, glass, ceramic, carbon (e.g., diamond), polycrystalline-Si, BN, or combinations thereof.

Referring to FIG. 5E, a patterned mask layer 530 is formed on the back surface of the thermal conductive layer 560. The patterned mask layer 530 may be formed according to any currently or later developed processes (e.g., photolithography process). The patterned mask layer 530 can be patterned to have one or more trenches 529 with any shape.

Referring to FIG. 5F, a deep trench is formed in the thermal conductive layer 560 and the semiconductor wafer 505 according to any suitable process(es), such as etching the thermal conductive layer 560 and the semiconductor wafer 505, followed by ashing and cleaning to remove residue materials. The forming of the deep trenches may be implemented according to any suitable etching process to transfer the patterns of the patterned mask layer 530 onto the thermal conductive layer 560 and the semiconductor wafer 505. The deep trench can include a backside trench 531 and a trench 535, divided by an extension plane of the backside surface 527 of the semiconductor wafer 505. The extension plane of the backside surface 527 refers to an imaginary plane coplanar with the backside surface 527 and extending between adjacent wafer portions 592 and 594. The trench 535 generally resembles the trench 335 in FIG. 3E. Although shown as being patterned in the same step, the sublayers of the thermal conductive layer 560 may be patterned in separate steps. In some examples, the metal layer 561 may be apart from adjacent metal layers 561, the distance between adjacent metal layers 561 in the x-direction may be greater than the width of the trench 535 in the x-direction.

In some examples, after the deep trench is formed, the thermal conductive layer 560 has any suitable thickness in the z-direction and any suitable width in the x-direction. For example, the thermal conductive layer 560 can have a thickness of about 1 μm to about 100 μm and a width of about 5 μm to about 10,000 μm. If the thickness and/or width is too small (e.g., less than about 0.1 μm), certain device features (such as heat transfer or mechanical support) may be compromised during operation. If the thickness and/or width is too large (e.g., greater than about 1,000,000 μm), benefit of the increased isolation may be offset by the extra processing and material cost. In some examples, the thermal conductive layer 560 has an aspect ratio greater than about 10:1, greater than about 100:1, or greater than about 1000:1. If the aspect ratio is too small (e.g., less than about 1:100), the height of the thermal conductive layer 560 may be large (e.g., impeding scaling-down of the IC 500).

Referring to FIG. 5G, an isolation dielectric material 528 is deposited onto the workpiece 502. In some examples, the isolation dielectric material 528 is deposited in the deep trench and, optionally, on the back surface of the thermal conductive layer 560. The deposition may be performed according to any suitable currently or later developed process(es). The isolation dielectric material 528 can be of the type described hereinabove. The isolation dielectric material 528 may be a traditional dielectric such as SiO₂, SiN, SiON, Spin-on-Glass (SOG), hydrogen silsesquioxane (HSQ), and Al₂O₃, or may be a polymeric dielectric material. A polymeric dielectric material can include parylene. In some examples, the polymeric dielectric material is selected from the group consisting of parylene-F, parylene—HTC, parylene-AF4, parylene C, parylene D, PTFE, polyimide, poly(p-phenylene-2,6-benzobisoxazole) (PBO), benzocyclobutene (BCB), Teflon, polyimide, and combinations thereof.

Referring to FIG. 5H, the isolation dielectric material 528 and the patterned mask layer 530 are exposed via etching or chemical-mechanical planarizing (CMP). The etching can be patterned or unpatterned. An unpatterned etchback by a O₂ based ash process can be suitable for a polymeric dielectric material. For example, after etching the back surface 541 of the thermal conductive layer 560 is exposed, as shown in FIG. 5H. An isolation segment 545 and an extension portion 540 collectively form an isolation element. The isolation segment 545 can be inside the trench 535 and generally resembles the isolation segment 345 and the isolation segment 245. The extension portion 540 extends from an extension plane of the backside surface 527 of the semiconductor wafer 505 and away from the front surface 534 of the trench 535. In some examples, the extension portion 540 interfaces with the thermal conductive layer 560 on a third side surface 543. The isolation dielectric material 528 can extend continuously from the isolation segment 545 to the extension portion 540. A back surface 542 of the extension portion 540 and the back surface 541 of the thermal conductive layer 560 can be in the same plane or in different planes. In some examples, the back surface 542 of the extension portion 540 is closer to the front side (as shown by the bold arrow 101) than the back surface 541 of the thermal conductive layer 560 is. The extension portion 540 can have any suitable thickness in the z-direction and any suitable width in the x-direction. For example, the extension portion 540 has a thickness in the z-direction of about 1 μm to about 100 μm and a width in x-direction of about 1 μm to about 50 μm. If the thickness and/or width is too small (e.g., less than about 0.001 μm), certain device features (increase isolation) may be compromised during operation. If the thickness and/or width is too large (e.g., greater than about 10,000 μm), benefit of the increased isolation may be offset by the extra processing and increased material cost. In some examples, the extension portion 540 has an aspect ratio of about 1:10 to about 100:1, from about 1:10 to about 50:1, or from about 1:10 to about 10:1. If the aspect ratio is too large (e.g., greater than about 10,000:1), the electrical isolation across the isolation element may be insufficient for some applications. If the aspect ratio is too small (e.g., less than about 1:1000), the isolation element may be large (e.g., impeding scaling-down of the IC 500). In some examples, the isolation dielectric material 528 in the isolation segment 545 and the extension portion 540 includes the same material or different materials. In the example shown in FIG. 5H, the isolation segment 545 fills the trenches 535 without leaving a gap. However, in other examples, a gap similar to the gap 246 of FIG. 2F may be formed in the trenches 535.

In some examples, although not shown in FIG. 5H, an additional isolation layer including an isolation dielectric material is deposited over the back surface 541 of the thermal conductive layer 560 and the back surface 542 of the extension portion 540. The isolation dielectric material can extend continuously from the extension portion 540 to the additional isolation layer. The additional isolation layer can have any suitable thickness, such as a thickness equal to or less than that of the extension portion 240, 340, or 440. In some examples, the thickness of the additional isolation layer is reduced (e.g., by etchback or patterned removal). The additional isolation layer can have a thickness of about 1 μm to about 40 μm, about 1 μm to about 20 μm, or about 1μm to about 10 μm. In some examples, an additional thermal conductive layer is deposited over the back surface of the additional isolation layer. The additional thermal conductive layer can include combinations of sublayers (e.g., a metal layer, a third dielectric layer, a diffusion barrier, and a polarization dielectric layer) similar to the thermal conductive layer 560. In such examples, the isolation segment 545, the extension portion 540, and the additional isolation layer collectively form the isolation element.

In some examples, the thermal conductive layer 560 and/or the additional thermal conductive layer increase a heat transfer rate of the IC 500. The thermal conductive layer 560 and/or the additional thermal conductive layer can have a thermal conductivity greater than the isolation element. By reducing the thickness and/or the width of the extension portion 540, a heat transfer rate through the isolation element can be increased. Therefore, the general heat transfer rate through the isolation element and the thermal conductive layer 560 and/or the additional thermal conductive layer can be increased.

In some examples, the thermal conductive layer 560 and/or the additional thermal conductive layer provides mechanical support to the extension portion 540, the isolation segment 545, and other parts of the IC 500. The mechanical support can prevent damages to the IC 500 caused by mechanical and thermal stresses.

Referring to FIG. 5I, the workpiece 502 is flipped and placed on a second carrier 555 which resembles the second carrier 355.

Referring to FIG. 5J, the first carrier is removed according to any currently or later developed process(es).

Referring to FIG. 5K, the workpiece 502 is cut by a severance 575, thereby severing the IC 500 from adjacent devices. In some examples, fabrication of the IC 500 is concluded following severing of the workpiece 502. In other examples, any suitable method can be useful to make the IC 500, which is contemplated by this description.

FIG. 5L is a cross-sectional view of a system 100D including the IC 500. Similar to the system 100 in FIG. 1, the system 100A in FIG. 2H, the system 100B in FIG. 3L, and the system 100C in FIG. 4E, the system 100D includes a package substrate 580, an attachment 585, and connections 590, each similar to the corresponding parts in FIGS. 1, 2H, 3L and 4E, respectively, as well as the IC 500. Although not specifically shown in FIG. 5L, the wafer portions 592 and 594 can include different circuits or sub devices similar to the sub-devices 207 described above. The isolation elements provided in FIG. 5L provides increased isolation between adjacent wafer portions 592 and 594, while also increasing structural integrity. In some examples, the system 100D includes regions that are isolated from the other regions by dielectric isolation. Isolated regions are those where the trench 535 completely surrounds one or more regions of the semiconductor wafer 505. These regions are then not connected by the semiconductor wafer 505 and are only physically connected by the isolation dielectric material. The isolation dielectric material prevents electrical connection (e.g., by the dielectric layer 510). In some examples, the circuits in these isolated regions generate an amount of parasitic heat. FIG. 5L shows a wire bond package, where most of the generated heat may flow from device region(s) at the front surface through the semiconductor wafer 505 to the package substrate 580 (e.g., a lead frame). By placing the isolation dielectric material 528 with thermal resistance at the bottom of the trench, the system 100D can have both voltage isolation and thermal resistance. The attachment 585 with high thermal conduction (e.g., metal die attach), a multi-metal lead frame, or combinations thereof. Herein, “high thermal conduction” is defined as having a thermal conductivity of equal to or greater than about 3 times of that of a polymer such as polyimide or parylene-F. A multi-metal lead frame refers to a lead frame having two or more metal layers.

In some examples, the IC 500 may be differently processed as shown in FIGS. 5M-5P, which continue from FIG. 5H. FIGS. 5M-5P are cross sectional views of the workpiece 502 at various processing stages of the fabrication of the IC 500, in various examples. In some examples, referring to FIG. 5M, a protection layer 565 is deposited onto the workpiece 502. In some examples, the protection layer 565 is deposited over the back surface 541 of the thermal conductive layer 560 and the back surface 542 of the extension portion 540. The protection layer 565 can include a metal layer, a dielectric layer, or a combination thereof. The protection layer 565 may prevent moisture from entering the extension portion 540 and/or the thermal conductive layer 560.

Alternatively, although not shown, an additional isolation layer and, optionally, an additional thermal conductive layer are deposited, as described above. In such examples, the protection layer 565 is deposited over the back surface of the additional thermal conductive layer and/or the additional isolation layer.

Similar to the workpiece 502 undergoing processing as shown in FIGS. 5I-5K, the workpiece 502 undergoes these modifications as shown in FIGS. 5N-5P, with the exception that the isolation element further includes the protection layer 565, as described above. Alternatively, any suitable method can be useful to make the IC 500, which is contemplated by this description.

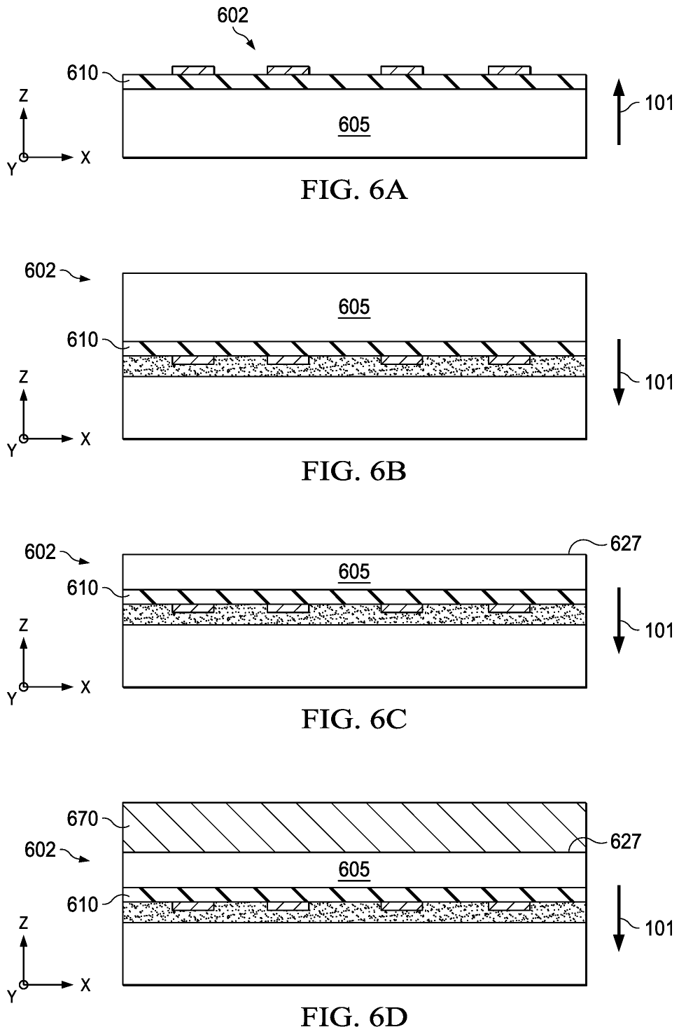

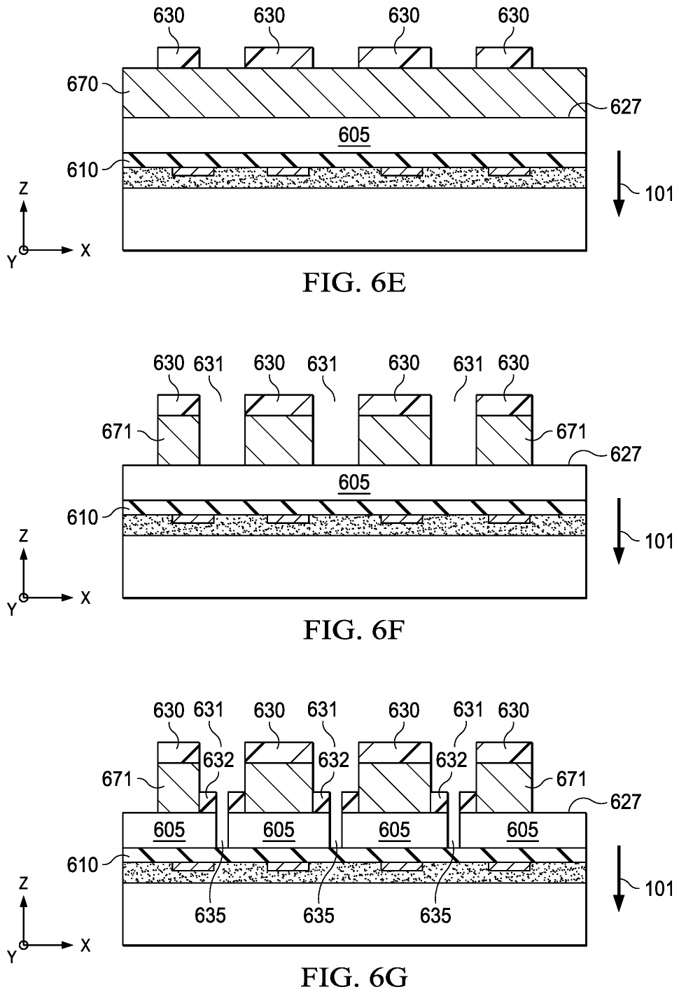

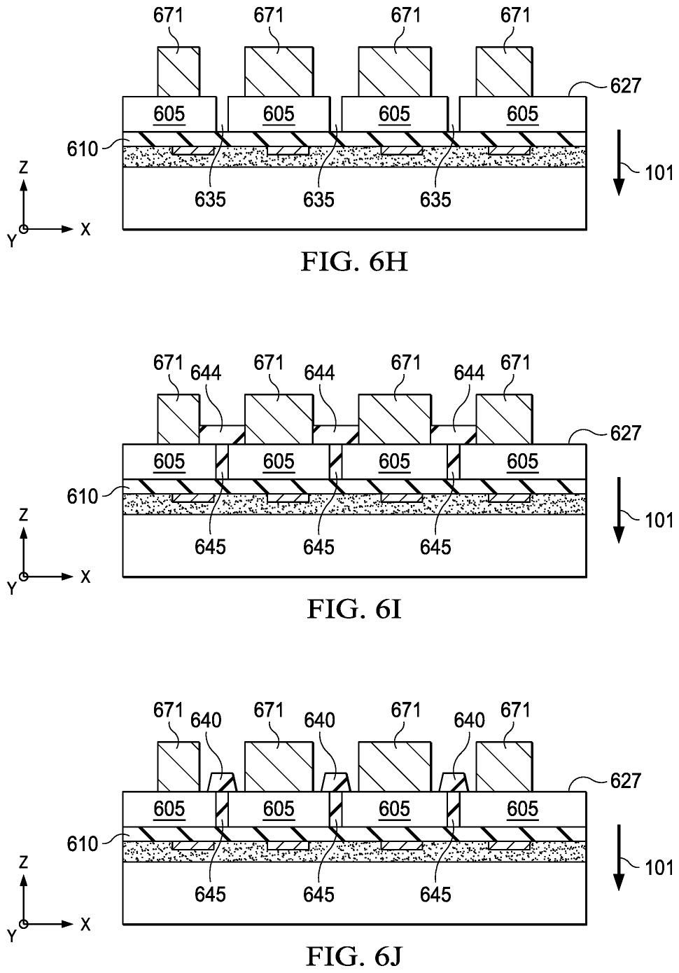

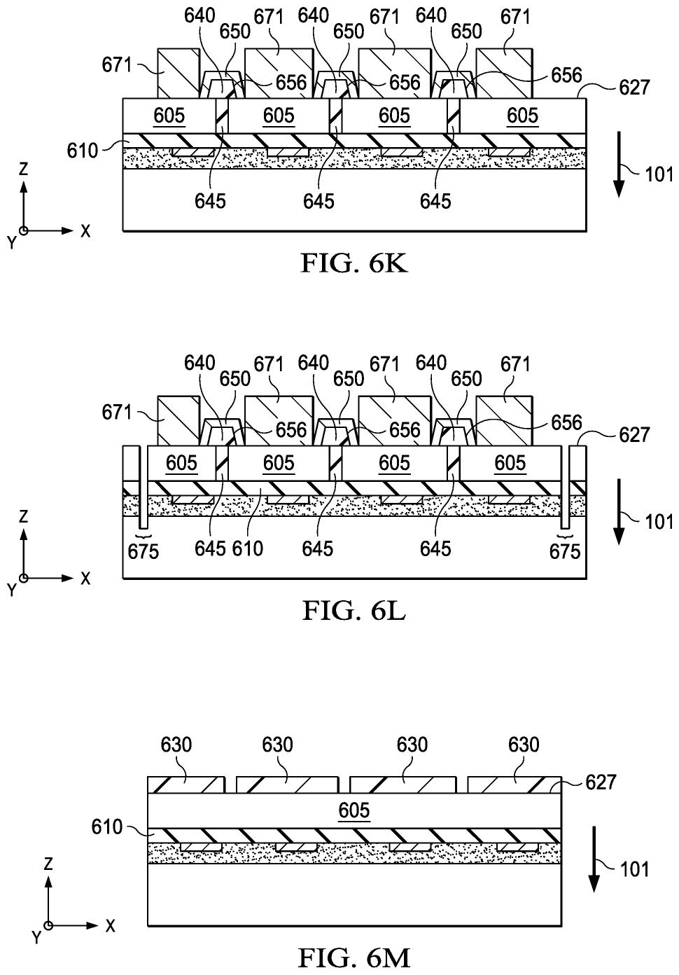

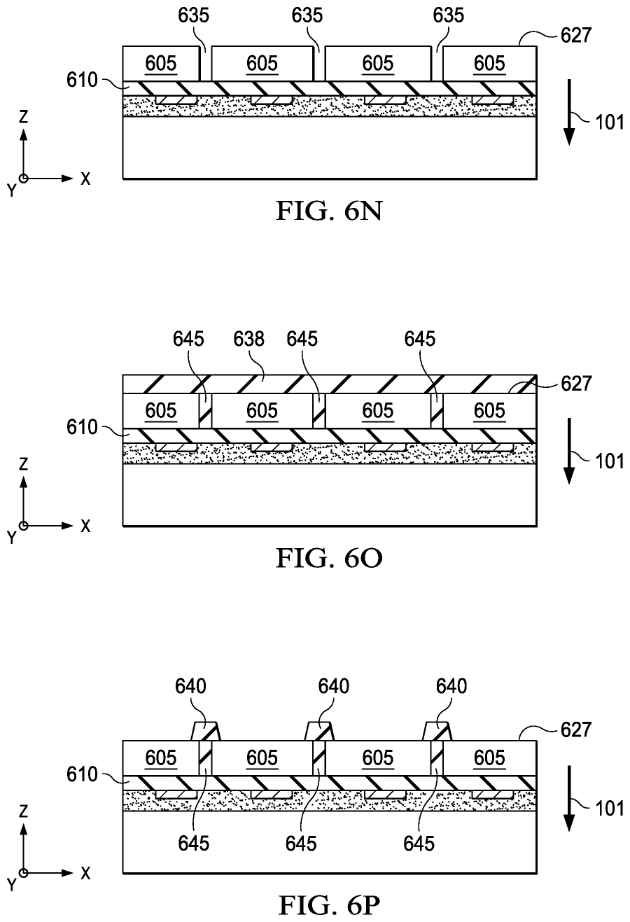

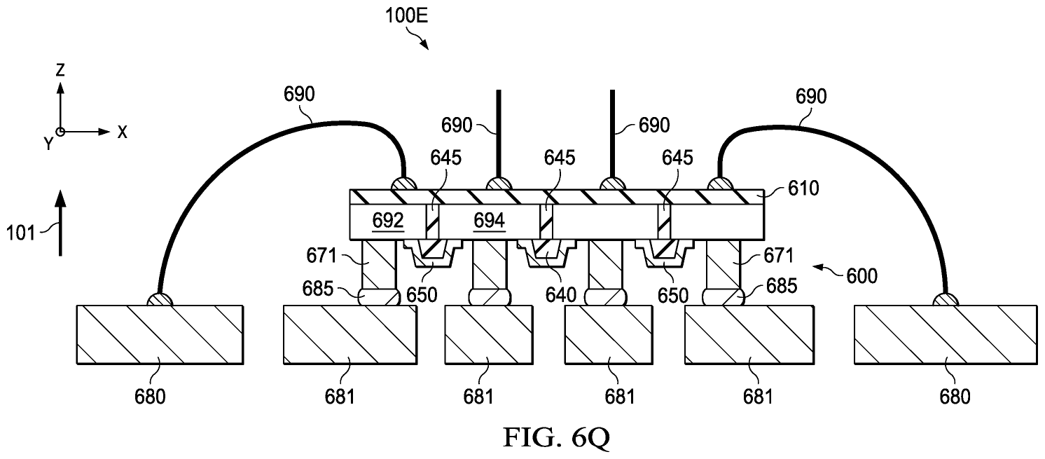

FIG. 5 provides an example structure for fabricating the IC 500. However, an IC may be fabricated according to another structure, such as shown in FIGS. 6A-6L, which may be collectively referred to as FIG. 6. FIGS. 6A-6L are cross sectional views of the workpiece 602 at various processing stages of the fabrication of the IC 600, in various examples. The IC 600 (or the workpiece 602) generally resemble the IC 500 (the workpiece 502), as described above with respect to FIGS. 5A-5P, with the exceptions as described as follows.

Similar to the workpiece 502 undergoing processing as shown in FIGS. 5A-5C, the workpiece 602 undergoes the modifications as shown in FIG. 6A-6C. Referring to FIG. 6D, a metal region layer 670 is deposited on the backside surface 627 of the semiconductor wafer 605. The deposition can include any suitable currently or later developed process(es). In some examples, the metal region layer 670 directly interfaces with and extends along the backside surface 527. The metal region layer 670 can have any suitable thickness in the z-direction and any suitable width in the x-direction. For example, the metal region layer 670 can have a thickness of about 1 μm to about 100 μm and a width of about 5 μm to about 10,000 μm. If the thickness and/or width is too small (e.g., less than about 0.001 μm), certain device features (such as coupling to a package substrate) may be compromised during operation. If the thickness and/or width is too large (e.g., greater than about 1,000,000 μm), benefit of increased isolation may be offset by the extra processing and material cost. In some examples, the metal region layer 670 includes any suitable metals, such as Al, Cu (e.g., electroplated Cu), Ag, W, Mo, steel, Ag—Pd based alloys, and combinations thereof. In some examples, the metal region layer 670 further includes a diffusion barrier layer having Ti, TiN, TiW, Co, Ru, Ta, TaN, or any other suitable materials. Depositing the metal region layer 670 can include depositing the diffusion barrier layer on the backside surface 627 of the semiconductor wafer 605 and then depositing the metal(s) on the diffusion barrier layer. In some examples, the diffusion barrier layer (e.g., TiW) and a seed layer (e.g., Cu) are deposited, followed by thick resist pattern, thick Cu electroplate with an optional solder layer on top, resist removal, and removal of the diffusion barrier layer and the seed layer (e.g., by wet etch).

Referring to FIG. 6E, a first patterned mask layer 630 is formed over the back surface of the metal region layer 670. The first patterned mask layer 630 may be formed according to any suitable currently or later developed process(es).

Referring to FIG. 6F, a wide trench 631 and a metal region 671 are formed according to any suitable process. In some examples, the wide trench 631 and the metal region 671 are formed by etching the metal region layer 670, followed by ashing and cleaning to remove residue materials. The forming of the wide trench 631 may be performed according to any suitable etching process to transfer the patterns of the first patterned mask layer 630 onto the metal region layer 670. At least a portion of the backside surface 627 of the semiconductor wafer 605 is exposed to the wide trench 631. The wide trench 631 can have any suitable width in the x-direction. For example, the wide trench 631 has a width in the x-direction of about 50 μm to about 1,000 μm. The metal region 671 can have any suitable cross-sectional shape, such as square or rectangle. The metal region 671 can have any suitable thickness (e.g., the same thickness as the metal region layer 670) in the z-direction and any suitable width in the x-direction. For example, the metal region 671 can have a thickness of about 1 μm to about 100 μm and a width of about 5 μm to about 100 μm. In some examples, the metal region 671 has an aspect ratio of about 1:5 to about 10:1, from about 1:2 to about 5:1, or from about 1:2 to about 2:1. If the aspect ratio is too large (e.g., greater than about 100:1), the metal region 671 may include an increased amount of metal; if the aspect ratio is too small (e.g., less than about 1:100), the metal region 671 may be large in the z-direction (e.g., impeding scaling-down of the IC 500).

Referring to FIG. 6G, a second patterned mask layer 632 is formed over the backside surface 627 of the semiconductor wafer 605 according to any suitable process. Referring to FIG. 6G, a trench 635 is formed in the semiconductor wafer 605 according to any suitable process(es), such as etching the semiconductor wafer 605, followed by ashing and cleaning to remove residue materials. The forming of the trenches may be performed according to any suitable etching process to transfer the patterns of the second patterned mask layer 632 onto the semiconductor wafer 605. The trench 635 generally resembles the trenches 235, 335, 435, and 535. FIG. 6G shows one trench 635 between two adjacent metal regions 671, but more than one of trenches 635 can be between two adjacent metal regions 671.

Referring to FIG. 6H, the first patterned mask layer 630 and the second patterned mask layer 632 are removed. The first patterned mask layer 630 and the second patterned mask layer 632 may be removed according to any suitable currently or later developed process(es). Following removal of the first patterned mask layer 630 and the second patterned mask layer 632 at least a portion of the backside surface 627 of the semiconductor wafer 605 is exposed to the trench 635. In some examples, the back surface of the metal region 671 may further be grinded or polished.

Referring to FIG. 6I, an isolation dielectric material of the type described above is deposited onto the workpiece 602. In some examples, the isolation dielectric material is deposited in the trench 635 and, optionally, on the backside surface 627 of the semiconductor wafer 605, to form an isolation segment 645 and a precursor extension portion 644. The isolation segment 645 may have the same dimension as the trench 635. In some examples, the precursor extension portion 644 extends on the backside surface 627 of the semiconductor wafer 605 between two adjacent metal regions 671. The precursor extension portion 644 can have any suitable thickness in the z-direction and any suitable width in the x-direction. In some examples, the precursor extension portion 644 has a thickness of about 1 μm to about 100 μm in the z-direction and a width of about 1 μm to about 1,000 μm in the x-direction. If the thickness and/or width is too small (e.g., less than about 0.001 μm), certain device features (such as increased isolation) may be compromised during operation. If the thickness and/or width is too large (e.g., greater than about 10,000 μm), benefit of the increased isolation may be offset by the extra processing and increased material cost. The isolation dielectric material can extend continuously from the isolation segment 645 to the precursor extension portion 644.

Referring to FIG. 6J, the isolation dielectric material in the precursor extension portion 644 is etched or undergoes CMP or any other suitable process to form the extension portion 640. The precursor extension portion 644 and the extension portion 640 generally resemble the precursor extension portion 444 and the extension portion 440, respectively. In some examples, the extension portion 640 and the isolation segment 645 collectively form the isolation element. This step can include any suitable currently or later developed process(es). The extension portion 640 can interface with the semiconductor wafer 605 on the backside surface 627. The extension portion 640 can have any suitable thickness in the z-direction and any suitable average width in the x-direction. In some examples, the extension portion 640 has a thickness in the z-direction that is equal to or less than that of the precursor extension portion 644. In some examples, the extension portion 640 has an average width in the x-direction that is equal to or less than that of the precursor extension portion 644. For example, the extension portion 640 has a thickness in the z-direction of about 1 μm to about 100 μm and an average width in the x-direction of about 1 μm to about 900 μm. If the thickness and/or width is too small (e.g., less than about 0.001 μm), certain device features (such as increased isolation) may be compromised during operation. If the thickness and/or width is too large (e.g., greater than about 10,000 μm), benefit of the increased isolation may be offset by the extra processing and increased material cost. In some examples, the cross section of the extension portion 640 has any suitable shape, such as square, rectangle, or trapezoid. In the example shown in FIG. 6J, the isolation segment 645 fills the trenches 635 without leaving a gap. However, in other examples, a gap similar to the gap 246 of FIG. 2F may be formed.

Referring to FIG. 6K, a support layer 650 (e.g., a dielectric layer) is deposited with pattern according to any suitable process(es). The support layer 650 generally resembles the support layer 450 in FIGS. 4C-4D. An interface 656 of the support layer 650 and a side surface of the extension portion 640 can intersect with the backside surface 627 of the semiconductor wafer 605. In some examples, the support layer 650 extends between two adjacent metal regions 671. The support layer 650 can include similar layers as the support layers 350 and 450. In some examples, the support layer 650 includes a metal layer, a second dielectric layer, a bonding layer, a diffusion barrier (also referred to as adhesion barrier), or combinations thereof. In some examples, the support layer 650 can be removed from the back surface of the metal regions 671 by mechanical or chemical mechanical polishing, or alternatively by an etch back process. For an etch back process, before removing the support layer 650, a polymer may be deposited in the wide trench 631 to protect the materials inside the wide trench 631.

Referring to FIG. 6L, the workpiece 602 is cut by a severance 675, thereby severing the IC 600 from adjacent devices. In some examples, the fabrication of the IC 600 is concluded following severing of the workpiece 602.

In some examples, the IC 600 may be differently processed as shown in FIGS. 6M-6P. FIGS. 6M-6P are cross sectional views of the workpiece 602 at various processing stages of fabrication of the IC 600, in various examples. In some examples, the IC 600 (or the workpiece 602) generally resemble the IC 600 (or the workpiece 602) described above with respect to FIGS. 6A-6L. The workpiece 602 undergoes the modifications as shown in FIGS. 6A-6C. Referring to FIG. 6M, a first patterned mask layer 630 is formed on the backside surface 627 of the semiconductor wafer 605. Referring to FIG. 6N, a trench 635 is formed in the semiconductor wafer 605 according to any suitable process, such as etching the semiconductor wafer 605, followed by ashing and cleaning to remove residue materials. Referring to FIG. 6O, an isolation dielectric material of the type described above is deposited onto the workpiece 602. In some examples, the isolation dielectric material is deposited in the trench 635 and, optionally, on the backside surface 627 of the semiconductor wafer 605, to form an isolation segment 645 and an alternate precursor extension portion 638. The alternate precursor extension portion 638 generally resembles the extension portion 340, and can extend on the backside surface 627 of the semiconductor wafer 605. Referring to FIG. 6P, the isolation dielectric material in the alternate precursor extension portion 638 may be patterned and etched to form the extension portion 640. In some examples, at least a portion of the alternate precursor extension portion 638 is removed, and at least a portion of the backside surface 627 of the semiconductor wafer 605 is exposed. The extension portion 640 generally resembles the extension portion 640 in FIG. 6J. Referring to FIG. 6J, a metal region 671 with a pattern is deposited over the backside surface 627 of the semiconductor wafer 605. Referring to FIG. 6K, a support layer 650 (e.g., a dielectric layer) with a pattern is deposited according to any suitable process. In some examples, the support layer 650 covers the back and side surfaces of the extension portion 640 and the backside surface 627 of the semiconductor wafer 605. In some examples, an order of depositing a support layer 650 and depositing a metal region 671 with a pattern can be switched. After modifications in FIGS. 6K and 6J, the workpiece 602 is severed similar to described above with respect to FIG. 6L. In some examples, the fabrication of the IC 600 is concluded following severing of the workpiece 602. In other examples, any suitable method can be useful to make the IC 600, which is contemplated by this description.

FIG. 6Q is a cross-sectional view of a system 100E including the IC 600. Similar to the system 100 in FIG. 1, the system 100A in FIG. 2H, the system 100B in FIG. 3L, the system 100C in FIG. 4E, and the system 100D in FIG. 5L, the system 100E herein includes a package substrate 680, an attachment 685, and connections 690, each similar to the corresponding parts in FIGS. 1, 2H, 3L, 4E and 5L, respectively, as well as the IC 600. Unlike the attachments 185, 285, 385, 485, and 585 in the examples above, as shown in FIG. 6Q, each attachment 685 connects a metal region 671 with an additional package substrate 681. Examples of the additional package substrate 681 include a lead frame, a circuit board, or another chip or wafer. The system 100E can include one or more of the metal regions 671 and each of them can be connected by an attachment 685 to an additional package substrate 681. Although not specifically shown in FIG. 6Q, the wafer portions 692 and 694 can include different circuits or sub devices similar to the sub-devices 207 described above. The isolation elements in FIG. 6Q provide increased isolation between adjacent wafer portions 692 and 694, while also increasing structural integrity of the IC 600.

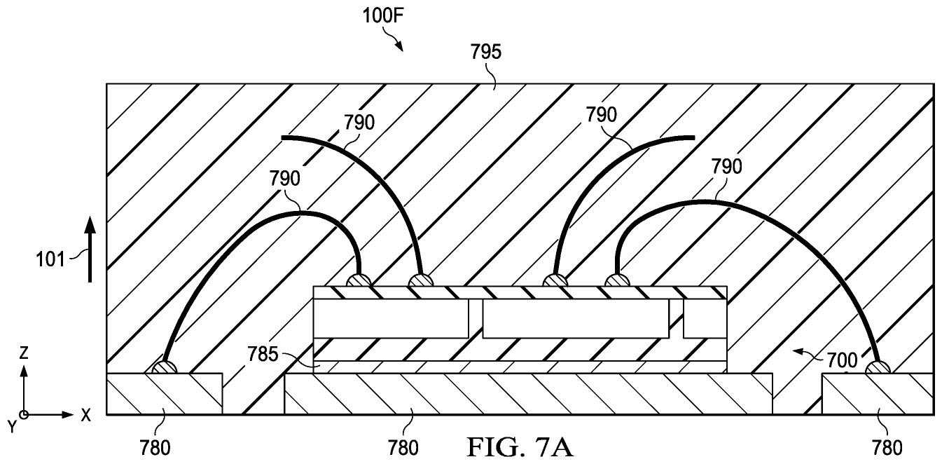

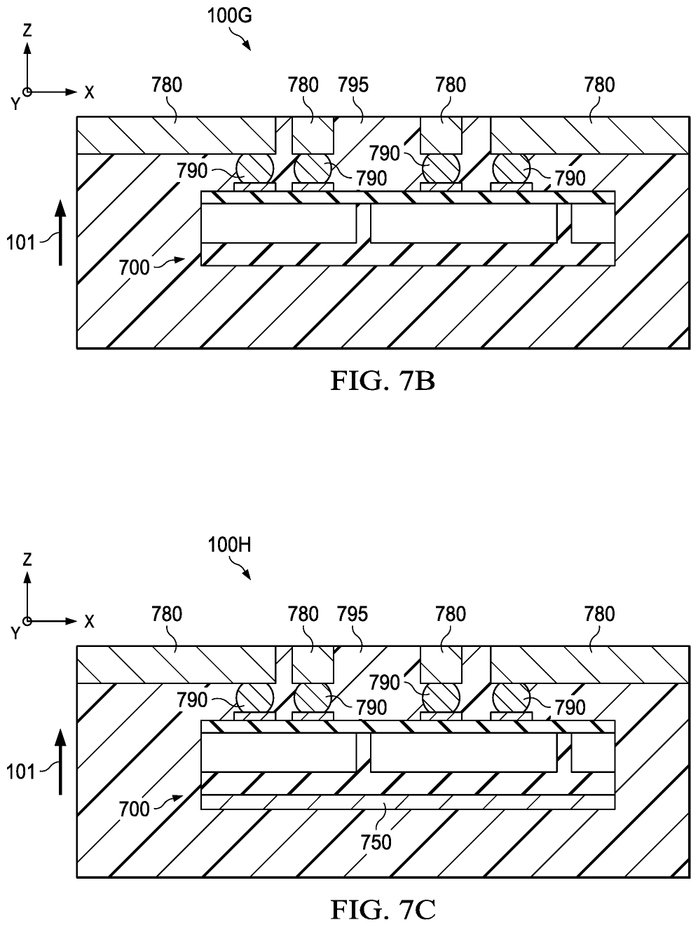

FIGS. 1, 2H, 3L, 4E, 5L and 6Q show examples of wire bond packages. However, other types of packages may be similarly prepared with the ICs described above. Examples of such packages may include solder-to-lead frame packages and wafer scale packages. FIGS. 7A-9 are cross-sectional views of systems including an IC as described above, in various examples. The system 100F in FIG. 7A is also a wire bond package and generally resembles the system 100A in FIG. 2H, except that the isolation element in FIG. 7A does not include a gap. The system 100G in FIG. 7B and the system 100H in FIG. 7C are solder-to-lead frame packages. Referring to FIGS. 7B-7C, the systems 100G and 100H each includes a package substrate 780, an IC 700, connections 790, and a package material 795. The connections 790 can include a solder bump (e.g., Au bump). In some examples, the package substrate 780 is positioned in front of the IC 700. The system 100H in FIG. 7C generally resembles the system 100G in FIG. 7B except that the IC 700 in FIG. 7C further includes a support layer 750.

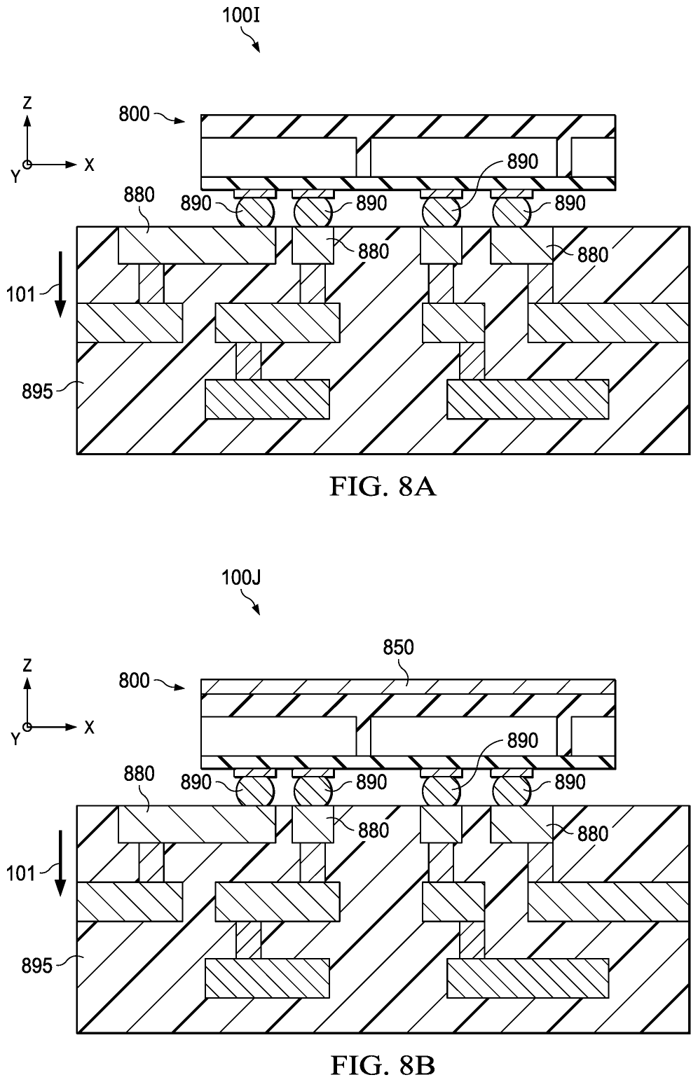

The system 100I in FIG. 8A and the system 100J in FIG. 8B are wafer scale packages. Referring to FIGS. 8A-8B, the systems 100I and 100J each include a package substrate 880, an IC 800, connections 890, and a package material 895. The connections 890 can include a solder bump or Au stud bump. In some examples, the solder bump includes a Cu layer (e.g., a Cu core) and a solder layer on top of the Cu layer. The solder layer can be thinner (e.g., a thickness in a radial direction) than the dimension of the Cu layer or the solder bump. In some examples, a dielectric material such as parylene or polyimide is on top surface of the solder bumps for insulation. In some examples, the dielectric material is on side surface of the solder bumps for insulation. The package substrate 880 can include more than one layer of conductive features, such as shown in FIGS. 8A-8B. The system 100J shown in FIG. 8B generally resembles the system 100I in FIG. 8A except that the IC 800 in FIG. 7B further includes a support layer 850.

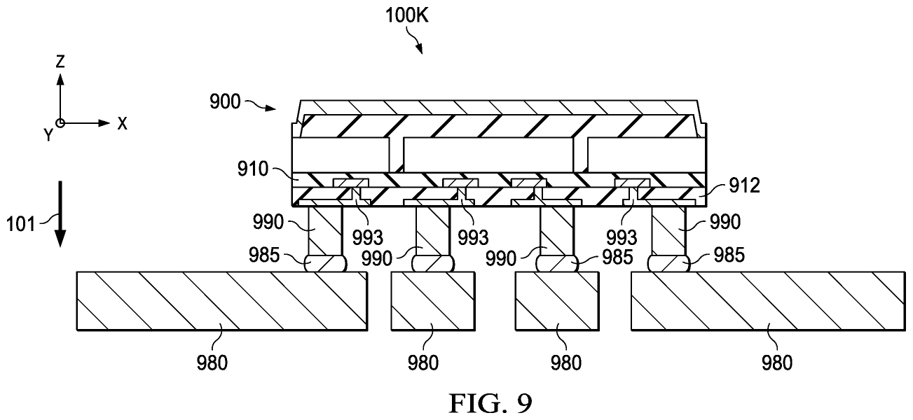

Referring to FIG. 9, the system 100K is a high-performance solder bump package. Such packages can also be referred to as wafer scale packages. Other similar packages can include surface mount, chip carrier, chip-scale packages, and ball grid array. In some examples, the system 100K includes package substrates 980, an IC 900, attachments 985, connections 990 (e.g., a metal element), a front dielectric layer 912 on the front side of the dielectric layer 910, and copper redistribution layers (RDL Cu) 993 embedded in the dielectric layer 910 and the front dielectric layer 912. In some examples, the RDL Cu 993, the connections 990, and the attachment 985, collectively couple the IC 900 to the package substrate 980. In some examples, the connections 990 includes multiple Cu layers with polyimide dielectric and Cu bumps (e.g., about 20 μm to about 100 μm) with a solder layer (e.g., about 3 μm to about 20 μm) on top. In some examples, an additional polymer coating such as polyimide is on the surfaces of the connections 990. In some examples, the additional polymer coating is not on the surfaces of the solder bumps. Although a package material is not shown in FIG. 9, the system 100K can further include a package material.

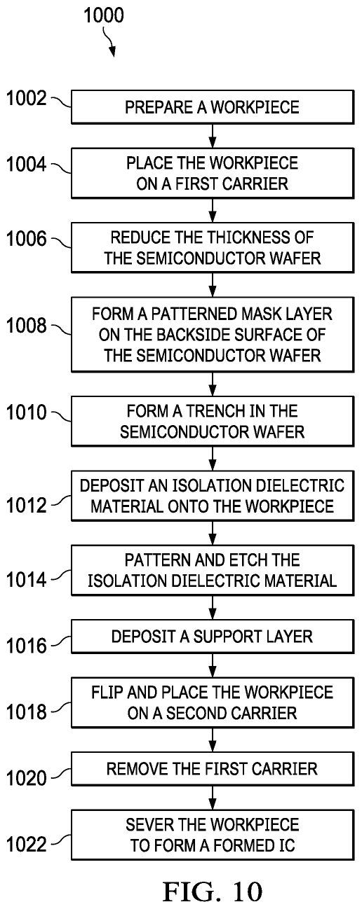

FIG. 10 is a flow diagram of a method 1000 of fabrication of an IC, in various examples, such as those described above with reference to FIGS. 1-9. Referring to block 1002, method 1000 includes preparing or receiving a workpiece. Referring to block 1004, method 1000 further includes placing the workpiece on a first carrier. Referring to block 1006, method 1000 further includes reducing a thickness of the semiconductor wafer. In some examples, reducing the thickness according to block 1006 is optional. Referring to block 1008, method 1000 further includes forming a patterned mask layer on the backside surface of the semiconductor wafer. Referring to block 1010, method 1000 further includes forming a trench in the semiconductor wafer. Referring to block 1012, method 1000 further includes depositing an isolation dielectric material onto the workpiece. Referring to block 1014, method 1000 further includes patterning and etching the isolation dielectric material. In some examples, patterning and etching the isolation dielectric material according to block 1014 is optional. Referring to block 1016, method 1000 further includes depositing a support layer. In some examples, depositing a support layer according to block 1016 is optional. Referring to block 1018, method 1000 further includes flipping the workpiece and placing the workpiece on a second carrier. In some examples, flipping the workpiece and placing the workpiece on a second carrier according to block 1018 is optional. Referring to block 1020, method 1000 further includes removing the first carrier. Referring to block 1022, method 1000 further includes severing the workpiece to form a formed IC.

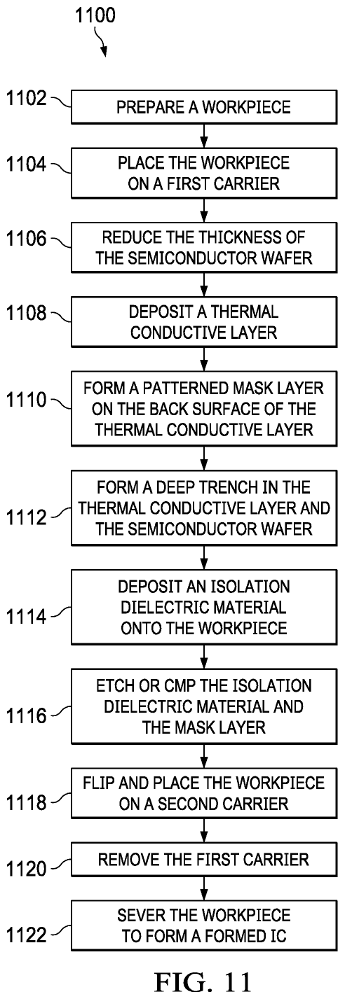

FIG. 11 is a flow diagram of a method 1100 of fabrication of an IC, in various examples, such as those described above with reference to FIGS. 1-9. Referring to block 1102, method 1100 includes preparing or receiving a workpiece. Referring to block 1104, method 1100 further includes placing the workpiece on a first carrier. Referring to block 1106, method 1100 further includes reducing thickness of the semiconductor wafer. In some examples, reducing the thickness according to block 1106 is optional. Referring to block 1108, method 1100 further includes depositing a thermal conductive layer. Referring to block 1110, method 1100 further includes forming a patterned mask layer on the back surface of the thermal conductive layer. Referring to block 1112, method 1100 further includes forming a deep trench in the thermal conductive layer and the semiconductor wafer. Referring to block 1114, method 1100 further includes depositing an isolation dielectric material onto the workpiece. Referring to block 1116, method 1100 further includes etching or chemical-mechanical planarizing (CMP) the isolation dielectric material and the mask layer. Referring to block 1118, method 1100 further includes flipping the workpiece and placing the workpiece on a second carrier. Referring to block 1120, method 1100 further includes removing the first carrier. Referring to block 1122, method 1100 further includes severing the workpiece to form a formed IC.

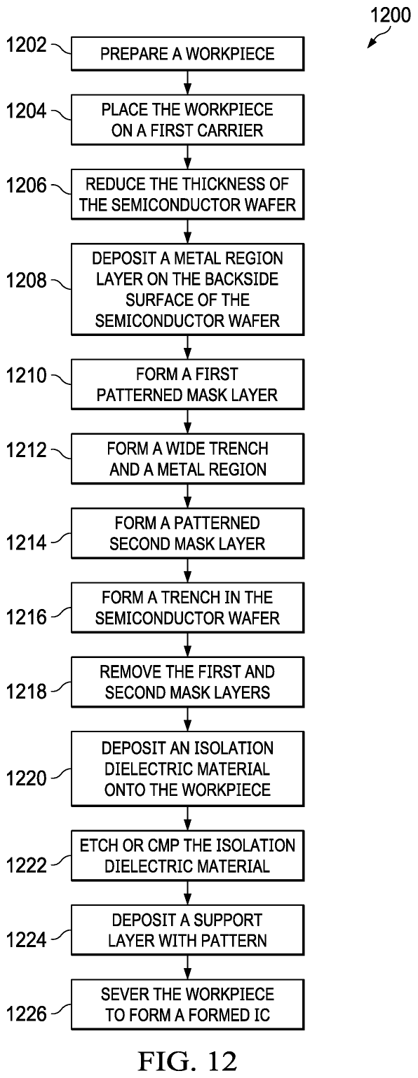

FIG. 12 is a flow diagram of a method 1200 of fabrication of an IC, in various examples, such as those described above with reference to FIGS. 1-9. Referring to block 1202, method 1200 includes preparing or receiving a workpiece. Referring to block 1204, method 1200 further includes placing the workpiece on a first carrier. Referring to block 1206, method 1200 further includes reducing thickness of the semiconductor wafer. In some examples, reducing the thickness according to block 1206 is optional. Referring to block 1208, method 1200 further includes depositing a metal region layer on the backside surface of the semiconductor wafer. Referring to block 1210, method 1200 further includes forming a first patterned mask layer. Referring to block 1212, method 1200 further includes forming a wide trench and a metal region. Referring to block 1214, method 1200 further includes forming a patterned second mask layer. Referring to block 1216, method 1200 further includes forming a trench in the semiconductor wafer. Referring to block 1218, method 1200 further includes removing the first and second mask layers. Referring to block 1220, method 1200 further includes depositing an isolation dielectric material onto the workpiece. Referring to block 1222, method 1200 further includes etching or chemical-mechanical planarizing (CMP) the isolation dielectric material. In some examples, etching or chemical-mechanical planarizing (CMP) the isolation dielectric material according to block 1222 is optional. Referring to block 1224, method 1200 further includes depositing a support layer with pattern. Referring to block 1226, method 1200 further includes severing the workpiece to form a formed IC.

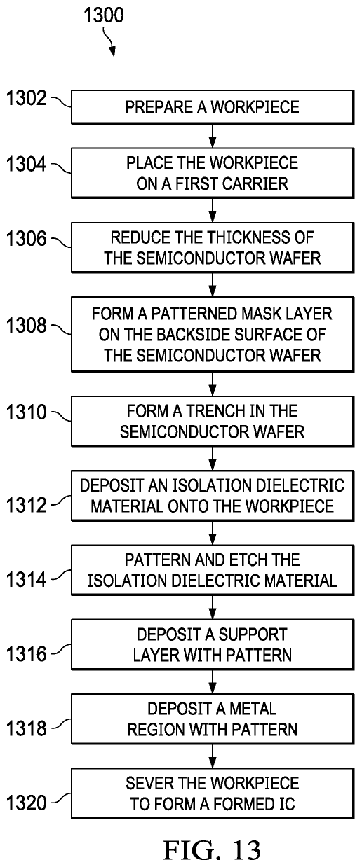

FIG. 13 is a flow diagram of a method 1300 of fabrication of an IC, in various examples, such as those described above with reference to FIGS. 1-9. Referring to block 1302, method 1300 includes preparing or receiving a workpiece. Referring to block 1304, method 1300 further includes placing the workpiece on a first carrier. Referring to block 1306, method 1300 further includes reducing thickness of the semiconductor wafer. In some examples, reducing the thickness according to block 1306 is optional. Referring to block 1308, method 1300 further includes forming a patterned mask layer on the backside surface of the semiconductor wafer. Referring to block 1310, method 1300 further includes forming a trench in the semiconductor wafer. Referring to block 1312, method 1300 further includes depositing an isolation dielectric material onto the workpiece. Referring to block 1314, method 1300 further includes patterning and etching the isolation dielectric material. Referring to block 1316, method 1300 further includes depositing a support layer with pattern. Referring to block 1318, method 1300 further includes depositing a metal region with pattern. In some examples, depositing a support layer with pattern according to block 1316 and depositing a metal region with pattern according to block 1318 can be switched. Referring to block 1320, method 1300 further includes severing the workpiece to form a formed IC.

The term “couple” is included throughout the specification. The term may cover connections, communications, or signal paths that enable a functional relationship consistent with this description. A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof. Unless otherwise stated, “about,” “approximately,” or “substantially” preceding a value means +/−10 percent of the stated value. Modifications are possible in the described examples, and other examples are possible within the scope of the claims.

What is claimed is:

1. An integrated circuit (IC), comprising:
a semiconductor wafer having a first wafer portion and a second wafer portion each extending from a frontside surface to a backside surface;
a dielectric layer interfacing with the first wafer portion and with the second wafer portion each on the frontside surface; and
an isolation element having an isolation dielectric material, the isolation element extending between a first side surface of the first wafer portion and a second side surface of the second wafer portion and from an extension plane of the frontside surface to an extension plane of the backside surface.

2. The IC of claim 1, wherein the isolation element includes an isolation segment between the first side surface and the second side surface, the isolation segment having an aspect ratio of 1:10 to 1:2.

3. The IC of claim 1, wherein the isolation element includes a gap therein.

4. The IC of claim 1, wherein the first wafer portion includes a first sub-device to receive a first voltage, the second wafer portion includes a second sub-device to receive a second voltage, and the first voltage and the second voltage have a difference in value of equal to or greater than 50% of a value of a smaller voltage of the first voltage and the second voltage.

5. The IC of claim 1, wherein the isolation dielectric material includes a polymer dielectric material, an inorganic dielectric material, or combinations thereof.

6. The IC of claim 5, wherein the polymer dielectric material includes parylene-F, parylene-HTC, parylene-AF4, parylene C, parylene D, polytetrafluoroethylene (PTFE), polyimide, poly(p-phenylene-2,6-benzobisoxazole) (PBO), benzocyclobutene (BCB), Teflon, polyimide, or combinations thereof.

7. The IC of claim 5, wherein the inorganic dielectric material includes silicon oxide (SiO₂), silicon oxynitride (SiON), silicon nitride (SiN), silicon oxynitrocarbide (SiONC), silicon carbide (SiC), aluminum nitride (AlN), aluminum oxide (Al₂O₃ or AlOₓ), boron nitride (BN), boron carbon nitride (BCN), spin-on-glass (SOG), hydrogen silsesquioxane (HSQ), diamond, or combinations thereof.

8. The IC of claim 1, wherein the isolation element includes an isolation segment between the first side surface and the second side surface, and an extension portion extending from the backside surface and an extension plane of the backside surface and away from the frontside surface, the isolation dielectric material extends continuously from the isolation segment to the extension portion, and the extension portion interfaces with the first wafer portion and with the second wafer portion each on the backside surface.

9. The IC of claim 8, wherein the extension portion has an aspect ratio of equal to or greater than 1:10.

10. The IC of claim 8, further comprising a support layer.

11. The IC of claim 10, wherein the support layer is disposed on and extending along a back surface of the extension portion.

12. The IC of claim 10, wherein the support layer is disposed on the backside surface.

13. The IC of claim 12, wherein an interface of the support layer and the extension portion intersects with the backside surface.

14. The IC of claim 10, wherein the dielectric layer is a first dielectric layer, and the support layer includes a metal layer, a second dielectric layer, a bonding layer, a diffusion barrier, a polarization dielectric layer, or combinations thereof.

15. The IC of claim 8, further comprising a metal region extending from the backside surface and away from the frontside surface.

16. The IC of claim 1, further comprising a thermal conductive layer disposed on and extending along the backside surface, wherein the isolation element includes an isolation segment between the first side surface and the second side surface, and an extension portion extending from an extension plane of the backside surface and away from the frontside surface, the isolation dielectric material extends continuously from the isolation segment to the extension portion, and the extension portion interfaces with a third side surface of the thermal conductive layer.

17. The IC of claim 16, wherein the dielectric layer is a first dielectric layer, and the thermal conductive layer includes a third dielectric layer, a metal layer, a diffusion barrier, a polarization dielectric layer, or combinations thereof.

18. An integrated circuit (IC), comprising:
a semiconductor wafer having a first wafer portion and a second wafer portion positioned juxtaposed with each other, wherein the first wafer portion has a first front surface and a first back surface, the second wafer portion has a second front surface and a second back surface, the first front surface coplanar with the second front surface, and the first back surface coplanar with the second back surface;
a dielectric layer interfacing with the first wafer portion on the first front surface and with the second wafer portion on the second front surface; and
an isolation element having an isolation dielectric material and extending between the first wafer portion and the second wafer portion, the isolation element interfacing with at least a portion of the first back surface and a portion of the second back surface.

19. The IC of claim 18, further comprising a support layer deposited on a back surface of the isolation element.

20. A system, comprising:
an IC, including:
a semiconductor wafer having a first wafer portion and a second wafer portion each extending from a frontside surface to a backside surface;
a dielectric layer interfacing with the first wafer portion and with the second wafer portion each on the frontside surface; and
an isolation element having an isolation dielectric material and extending between a first side surface of the first wafer portion and a second side surface of the second wafer portion and from an extension plane of the frontside surface to an extension plane of the backside surface; and
a package substrate coupled to the IC.
